(19) United States
(12) Patent Application Publication
(10) Pub. No.: US 2023/0130402 A1
(43) Pub. Date: Apr. 27, 2023

(54) METHOD AND APPARATUS FOR DESIGNING MAGNETIC SHIELDING APPARATUS AND MAGNETIC SHIELDING APPARATUS

(71) Applicants: Peking University, Beijing (CN); Beijing QuanMag Healthcare Co. Ltd., Beijing (CN)

(72) Inventors: Jia-Hong GAO, Beijing (CN); Dongxu LI, Beijing (CN); Jingwei SHENG, Beijing (CN)

(73) Assignees: Peking University, Beijing (CN); Beijing QuanMag Healthcare Co. Ltd., Beijing (CN)

(21) Appl. No.: 17/946,241

(22) Filed: Sep. 16, 2022

(30) Foreign Application Priority Data
Oct. 25, 2021 (CN) 202111243525.4

(51) Int. Cl. H05K 9/00

(52) U.S. Cl. CPC H05K 9/0075; H05K 9/0088

(57) ABSTRACT

Disclosed are a method and an apparatus for designing a magnetic shielding apparatus and a magnetic shielding apparatus. The method includes: determining a region of interest inside the magnetic shielding apparatus, the region of interest being a region where a magnetic shielding effect is expected to be achieved, and the magnetic shielding apparatus including N layers of shields disposed in a nested manner; determining a complete parameter set; and obtaining, based on the complete parameter set, a set of result parameters for describing the geometric structure, the set of result parameters that enables magnetic flux density in the region of interest to meet a preset threshold. This method not only greatly improves optimized magnetic shielding performance compared with an equal-spacing solution, but also resolves a problem that an analytical method cannot be used to optimize a magnetic shielding apparatus with a non-concentric structure.

### CROSS-REFERENCE TO RELATED APPLICATIONS

The application claims priority to Chinese Patent Application CN202111243525.4, filed on Oct. 25, 2021, the entire contents of which are incorporated herein by reference.

### TECHNICAL FIELD

The present application relates to the technical field of magnetic shielding apparatuses, and specifically, to a method and an apparatus for designing a magnetic shielding apparatus, a non-transitory computer-readable storage medium, an electronic device, software, and a magnetic shielding apparatus.

### BACKGROUND

In many cases, people need to measure weak magnetic field signals or carry out an experiment in a weak magnetic field environment. To achieve conditions for carrying out the foregoing experiment, interference of the earth's magnetic field and other interference sources needs to be shielded to create a weak magnetic field environment. Currently, a recognized implementation method is to use a high-permeability magnetic material to construct a multi-layer shielding cavity, so as to form a magnetic shielding apparatus. Basic geometric structures that can be adopted by the magnetic shielding apparatus include football shape (such as Japanese COSMOS magnetic shielding apparatus), cylindrical shape, cuboid (such as the Berlin magnetically shielded room (BMSR) in Germany), etc. Generally, the higher the symmetry is, the better the magnetic shielding effect may be, and the greater the processing difficulty will be. A cylindrical magnetic shield has cylindrical symmetry and is easy to process, which can achieve a good magnetic shielding effect at a low cost and be processed into a small magnetic shielding apparatus, or a medium-large magnetic shielding apparatus. Magnetic shielding performance of the cylindrical magnetic shield is best when bottom surfaces at both ends are closed. However, in some cases, a cylindrical magnetic shield with an open end needs to be designed and manufactured. In the prior art, this is accomplished by removing a cover at one end of an existing cylindrical magnetic shield with both ends closed. The cylindrical magnetic shield with both ends closed has good performance even if there is no special optimization design. For example, a solution of equal spacing or approximately equal spacing between layers is adopted by most manufacturers. Therefore, the optimization design is not performed for parameters of the geometric structure of the cylindrical magnetic shield. However, if the cylindrical magnetic shield with an open end also adopts the geometric structure similar to that of the cylindrical magnetic shield with both ends closed, the magnetic shielding performance may deteriorate. Similarly, for a magnetic shielding apparatus with other basic geometric structures, simply adding an open structure may significantly reduce the magnetic shielding performance of the magnetic shielding apparatus.

In view of this, it is urgent to provide a method for the optimization design of the magnetic shielding apparatus, to improve the shielding performance of the magnetic shielding apparatus.

### SUMMARY

In view of this, embodiments of the present application provide a method for designing a magnetic shielding apparatus, a non-transitory computer-readable storage medium, an electronic device, a software product, and a magnetic shielding apparatus, to implement optimization of performance of the magnetic shielding apparatus by constructing a complete parameter set and optimizing parameters therein.

According to a first aspect, an embodiment of the present application provides a method for designing a magnetic shielding apparatus, including:

determining a region of interest inside the magnetic shielding apparatus, wherein the region of interest is a region where a magnetic shielding effect is expected to be achieved and the magnetic shielding apparatus includes N layers of shields disposed in a nested manner;

determining a complete parameter set, wherein the complete parameter set is used to describe a geometric structure of at least one layer of shield in the N layers of shields and a relative positional relationship between the region of interest and each layer of shield of the at least one layer of shield; and

obtaining, based on the complete parameter set, a set of result parameters for describing the geometric structure, wherein the result parameters enable magnetic flux density in the region of interest to meet a preset threshold.

In some embodiments of the present application, the obtaining, based on the complete parameter set, a set of result parameters for describing the geometric structure includes:

inputting the complete parameter set as independent variables and the magnetic flux density in the region of interest as a dependent variable into a derivative-free optimization model to obtain a set of optimal parameters though calculation of the derivative-free optimization model, wherein the independent variables include non-monotonically increasing independent variables, and the dependent variable does not increase monotonically when the non-monotonically increasing independent variables increase, and constants are set to define upper bounds of the non-monotonically increasing independent variables in the derivative-free optimization model; and

verifying whether the non-monotonically increasing independent variables in the optimal parameters reach the upper bounds defined by the constants,

if yes, increasing the constants of the derivative-free optimization model and then re-executing the step of inputting the complete parameter set as the independent variables and the magnetic flux density in the region of interest as the dependent variable into the derivative-free optimization model;

if no, verifying whether the magnetic flux density in the region of interest of the magnetic shielding apparatus with the optimal parameters meets the preset threshold; and if yes, outputting results, wherein the results output are result parameters; if no, adjusting an input of the derivative-free optimization model, and then re-executing calculation of the derivative-free optimization model.

In some embodiments of the present application, the inputting the complete parameter set as independent variables and the magnetic flux density in the region of interest as a dependent variable into a derivative-free optimization model to obtain a set of optimal parameters includes: obtaining optimization parameters based on the complete parameter set through calculation of the derivative-free optimization model, converting the optimization parameters into the magnetic flux density by using a method for obtaining magnetic field distribution of the magnetic shielding apparatus from the geometric structure, and obtaining the optimal parameters and the magnetic flux density in the region of interest of the magnetic shielding apparatus with the optimal parameters by using repeated calculation or iterative calculation during calculation of the derivative-free optimization model.

In some embodiments of the present application, the using repeated calculation during calculation of the derivative-free optimization model includes: during calculation of the derivative-free optimization model, calculating objective function values corresponding to all parameter combinations according to a rule of the repeated calculation; selecting the optimal parameters corresponding to a minimum objective function value; and obtaining the value and a corresponding magnetic flux density in the region of interest of the magnetic shielding apparatus with the optimal parameters.

In some embodiments of the present application, the using iterative calculation during calculation of the derivative-free optimization model includes: during calculation of the derivative-free optimization model, obtaining new optimization parameters based on values of parameters to be optimized and a corresponding objective function value used in previous calculation; and performing calculation continuously according to an iteration termination condition until the optimal parameters and the magnetic flux density in the region of interest of the magnetic shielding apparatus with the optimal parameters are obtained.

In some embodiments of the present application, the method for obtaining the magnetic field distribution of the magnetic shielding apparatus from the geometric structure includes a finite element method.

In some embodiments of the present application, basic geometric structures of the N layers of shields are the same and all have symmetry, and the region of interest is a three-dimensional space.

In some embodiments of the present application, a center of the region of interest is on a symmetry plane of the N layers of shields.

In some embodiments of the present application, the N layers of shields have rotational symmetry, and the center of the region of interest is on an axis of symmetry of the N layers of shields.

In some embodiments of the present application, the region of interest has axial symmetry, and an axis of symmetry of the region of interest coincides with the axis of symmetry of N layers of shields.

In some embodiments of the present application, the determining a complete parameter set includes: determining basic parameters of the magnetic shielding apparatus according to the preset threshold of the magnetic flux density of the region of interest; and

determining the complete parameter set according to the basic parameters, wherein the basic parameters include parameters used to represent a basic geometric structure of the magnetic shielding apparatus, a quantity of layers of shields included by the magnetic shielding apparatus, materials of the N layers of shields, a thickness of each layer of shields, a size of the region of interest, and a position of the region of interest relative to the magnetic shielding apparatus.

In some embodiments of the present application, the obtaining, based on the complete parameter set, a set of result parameters for describing the geometric structure includes: determining constraints; and obtaining, based on the constraints and the complete parameter set, the set of result parameters for describing the geometric structure, wherein the constraints limit a range of parameters in the complete parameter set.

In some embodiments of the present application, the method for designing a magnetic shielding apparatus further includes: selecting, based on the complete parameter set, independent parameters having the same quantity of parameters as the complete parameter set, wherein the independent parameters have the same completeness as the complete parameter set and are used to completely describe the geometric structure; constructing first-level generalized coordinates based on the independent parameters; and obtaining, based on the complete parameter set, parameters that describe differential characteristics of the geometric structure in the first-level generalized coordinates.

In some embodiments of the present application, the method for designing a magnetic shielding apparatus further includes: constructing second-level generalized coordinates based on the first-level generalized coordinates; and normalizing the first-level generalized coordinates by using the second-level generalized coordinates.

In some embodiments of the present application, the basic geometric structure of the magnetic shielding apparatus is a geometric structure provided with at least one opening structure, and centers of the basic geometric structures of the N layers of shields do not coincide with each other, wherein the opening structure connects the region of interest with outer space of the N layers of shields.

In some embodiments of the present application, the basic geometric structure of the magnetic shielding apparatus is a cylindrical structure with cylindrical symmetry and a single end open, a ring structure extending in a direction from an outer edge of the shield to the axis of symmetry of the cylindrical structure is provided at an opening of at least one layer of shield in the N layers of shields, and the ring structure shields a gap, perpendicular to a direction of the axis of symmetry, between adjacent shields; and

the complete parameter set is used to represent parameters of a symmetrical section of the cylindrical structure, wherein the symmetrical section refers to a half-plane passing through the axis of symmetry and using the axis of symmetry as a boundary.

In some embodiments of the present application, the ring structure is provided at an opening of each of N−1 layers of shields, in the N layers of shields, except an innermost layer of shield.

In some embodiments of the present application, the complete parameter set includes a radius Rᵢ of a bottom surface of the cylindrical structure, an axial distance L_{Ai} from the bottom surface to the center of the region of interest, an axial distance L_{Bi} from each layer of shield in the N layers of shields to the center of the region of interest, and a width Cᵢ of the ring structure, wherein i denotes the i^{th} layer of shield, wherein

when each layer of shield in the N layers of shields is provided with the ring structure, L_{Bi} is an axial distance from a geometric center, namely, a center of mass, of the ring structure to the center of the region of interest; and

when at least one layer of shield in the N layers of shields is not provided with the ring structure, for the shield not provided with the ring structure, L_{Bi} is an axial distance from an outer edge of the corresponding shield not provided with the ring structure to the center of the region of interest; and for the shield, in the N layers of shields, provided with the ring structure, L_{Bi} is an axial distance from the geometric center, namely, the center of mass, of the ring structure to the center of the region of interest.

In some embodiments of the present application, range limits are imposed on the parameters in the complete parameter set by the constraints, where the constraints include:

an outer-size constraint, used to define a maximum outer boundary of the magnetic shielding apparatus;

an inner-size constraint, used to define a minimum internal space of the magnetic shielding apparatus;

a spacing constraint, used to define a minimum spacing between the adjacent shields;

a minimum-width constraint, used to define a minimum width of the ring structure; and

a region-of-interest constraint, used to define a minimum axial distance from the region of interest to a bottom surface of the innermost layer of shield of the magnetic shielding apparatus.

In some embodiments of the present application, the constraints further include an additional constraint, and the additional constraint is used to limit a radius difference of outer layers of the adjacent shields to be greater than that of inner layers of the adjacent shields, that is, Rᵢ₊₁−Rᵢ>Rᵢ−Rᵢ₋₁.

According to a second aspect, an embodiment of the present application provides a non-transitory computer-readable storage medium. The storage medium stores a computer program, and the computer program is used to perform any aspect of the method for designing a magnetic shielding apparatus.

According to a third aspect, an embodiment of the present application provides an electronic device. The electronic device includes a processor and a memory configured to store an instruction executable by the processor, where the processor is configured to perform any aspect of the method for designing a magnetic shielding apparatus.

According to a fourth aspect, an embodiment of the present application provides a software product. The software product runs any aspect of the method for designing a magnetic shielding apparatus.

According to a fifth aspect, an embodiment of the present application provides a magnetic shielding apparatus, including: N layers of shields nested together, wherein N>1, and the magnetic shielding apparatus is designed based on any aspect of the method for designing a magnetic shielding apparatus.

In some embodiments of the present application, there is a length difference between adjacent shields of the N layers of shields at at least one of two ends in a working direction of the magnetic shielding apparatus, and/or there is an assembly gap between the adjacent shields in the N layers of shields in a direction perpendicular to a working direction of the magnetic shielding apparatus, and the length difference and the assembly gap are designed based on the method for designing a magnetic shielding apparatus. The magnetic shielding apparatus is provided with an access channel for a sample to be tested, and the access channel may be closed by a cover. The working direction of the magnetic shielding apparatus is a direction of a straight line between the center of the region of interest and a geometric center of a closed curve (an edge of an opening) formed in an outermost shield when the access channel for the sample to be tested is not closed by the cover. The sample to be tested includes any one or more of light, an object and a human body. Certainly, the length difference and the assembly gap between the shields are not limited to be disposed in a direction relative to the working direction in the foregoing embodiments.

In some embodiments of the present application, at least three layers of shields are provided for the N layers of shields, and at least two assembly gaps between every two adjacent shields are not equal and/or at least two length differences between every two adjacent shields are not equal.

In some embodiments of the present application, basic geometric structures of the N layers of shields of the magnetic shielding apparatus are the same and all have symmetry; an opening is provided at an end of the N layers of shields in an axial direction of an axis of symmetry of the N layers of shields, to form an open end of the magnetic shielding apparatus, and the other end disposed opposite to the open end is a closed end of the magnetic shielding apparatus; and the length differences of the N layers of shields are formed near the open end of the magnetic shielding apparatus.

In some embodiments of the present application, an open end of at least one layer of shield in the N layers of shields is provided with a shielding structure extending in a direction from an outer edge of the shield to the axis of symmetry of the N layers of shields, and the assembly gaps are formed between shielding structures of different layers in a direction perpendicular to the axis of symmetry of the N layers of shields.

In some embodiments of the present application, an outer edge of an innermost layer of shield in the N layers of shields is stretched in a direction perpendicular to a plane where the opening is located to form a curved surface, and the shielding structure extends to the curved surface.

In some embodiments of the present application, the shielding structure is provided at an opening of each layer of N−1 layers of shields, in the N layers of shields, except an innermost layer of shield.

In some embodiments of the present application, the basic geometric structures of the N layers of shields are cylindrical structures with cylindrical symmetry, and the shielding structure is a ring structure.

According to a sixth aspect, an embodiment of the present application provides an apparatus for designing a magnetic shielding apparatus, including:

a first determining module, configured to determine a region of interest inside the magnetic shielding apparatus, wherein the region of interest is a region where a magnetic shielding effect is expected to be achieved, and the magnetic shielding apparatus includes N layers of shields disposed in a nested manner;

a second determining module, configured to determine a complete parameter set, where the complete parameter set is used to describe a geometric structure of at least one layer of shield in the N layers of shields and a relative positional relationship between the region of interest and each layer of shield in the at least one layer of shield; and

a parameter optimization module, configured to obtain, based on the complete parameter set, a set of result parameters for describing the geometric structure, wherein the result parameters enable magnetic flux density in the region of interest to meet a preset threshold.

The embodiments of the present application provide a method and an apparatus for designing a magnetic shielding apparatus, and a magnetic shielding apparatus. In the method, the region of interest and the complete parameter set are provided, and parameters in the complete parameter set are optimized to implement optimization of performance of the magnetic shielding apparatus.

### BRIEF DESCRIPTION OF THE DRAWINGS

FIG. 1 is a schematic flowchart of a method for designing a magnetic shielding apparatus according to an exemplary embodiment of the present application.

FIG. 2 is a schematic flowchart of a method for designing a magnetic shielding apparatus according to an exemplary embodiment of the present application.

FIG. 3 is a three-dimensional schematic view of a magnetic shielding apparatus to be optimized according to an exemplary embodiment of the present application.

FIG. 4 is a schematic diagram of a two-dimensional cross-section of a magnetic shielding apparatus to be optimized according to an exemplary embodiment of the present application.

FIG. 5 is a schematic structural diagram of each layer of shield of a magnetic shielding apparatus to be optimized according to an exemplary embodiment of the present application.

FIG. 6 is a schematic structural diagram of a symmetrical section of a magnetic shielding apparatus to be optimized in a three-dimensional view according to an exemplary embodiment of the present application.

FIG. 7 is a schematic structural diagram of a symmetrical section of a magnetic shielding apparatus to be optimized in a two-dimensional cross-sectional view according to an exemplary embodiment of the present application.

FIG. 8 is a schematic structural diagram of each layer, in a symmetrical section, of the magnetic shielding apparatus to be optimized according to an exemplary embodiment of the present application.

FIG. 9 is a schematic structural diagram of a cylindrical region of interest in a symmetrical section according to an exemplary embodiment of the present application.

FIG. 10 shows a complete parameter set required to describe a single layer of a structure (the i^{th} layer) and a region of interest according to an exemplary embodiment of the present application.

FIG. 11 is a two-dimensional cross-sectional view of an equal-spacing solution of a magnetic shielding apparatus to be optimized according to an exemplary embodiment of the present application.

FIG. 12 is a three-dimensional schematic view of an optimized magnetic shielding apparatus according to an exemplary embodiment of the present application.

FIG. 13 is a two-dimensional cross-sectional view of an optimized magnetic shielding apparatus according to an exemplary embodiment of the present application.

FIG. 14 is a schematic flowchart of a method for designing a cylindrical magnetic shield with a single end open and a plurality of layers nested according to an exemplary embodiment of the present application.

### DETAILED DESCRIPTION OF THE EMBODIMENTS

The following clearly and completely describes the technical solutions in the embodiments of the present application with reference to the accompanying drawings in the embodiments of the present application. Apparently, the described embodiments are merely some but not all of the embodiments of the present application. All other embodiments obtained by a person of ordinary skill in the art based on the embodiments of the present application without creative efforts shall fall within the protection scope of the present application.

Application Overview

There are many factors that influence performance of a magnetic shielding apparatus, including material selection, a geometric structure, an annealing and assembly process, a demagnetization method, etc. A closed magnetic shielding apparatus has the best performance; however, in some cases, a magnetic shielding apparatus with an opening needs to be designed and manufactured. For example, when a human magnetic signal (magnetocardiogram, magnetoencephalogram) is measured, a structure of the magnetic shielding apparatus with the opening ensures comfort and safety of a subject. For example, an experimental apparatus served by the magnetic shielding apparatus has a large cross-section part penetrating interior and exterior of a cavity. Specifically, the magnetic shielding apparatus may allow a sample to be transferred from outside into the cavity of the magnetic shielding apparatus by using a mechanical arm and vacuum flange in vacuum in a condensed matter physics or material physics experiment. In another example, the magnetic shielding apparatus provides an opening for large cross-section light path in an atomic physics experiment. In the foregoing cases, the magnetic shielding apparatus may need to be designed as a structure with an opening. The opening does not mean a small hole drilled in the magnetic shielding apparatus, but refers to an opening whose smallest dimension exceeds 15% of the largest dimension of an entire apparatus. For example, a cylinder with a length of 1 m and a radius of 0.4 m is provided with an elliptical hole somewhere, a major axis of the ellipse is 0.2 m, and a minor axis is 0.1 m. Since 0.1 m<1 m×15%, the hole is not considered to be an opening. If the major axis of the ellipse is 0.2 m and the minor axis is 0.19 m, as 0.19 m>1 m×15%, the hole is considered to be an opening.

For example, for a common cylindrical magnetic shield, the cylindrical magnetic shield obtained based on a solution of equal spacing or approximately equal spacing between layers of shields of the cylindrical magnetic shield with both ends closed may meet application requirements without special optimization design. A design solution currently adopted by most manufacturers is to open one end of the existing cylindrical magnetic shield with both ends closed, so that the existing cylindrical magnetic shield becomes a magnetic shielding apparatus with a single end open. However, compared with the magnetic shielding performance of the cylindrical magnetic shield with both ends closed, the magnetic shielding performance of a cylindrical magnetic shield with an opening is greatly attenuated due to design of the opening. This problem also exists in designs of magnetic shielding apparatuses with other basic geometric structures. Therefore, an optimization design solution for a magnetic shielding apparatus needs to be provided.

Exemplary Method

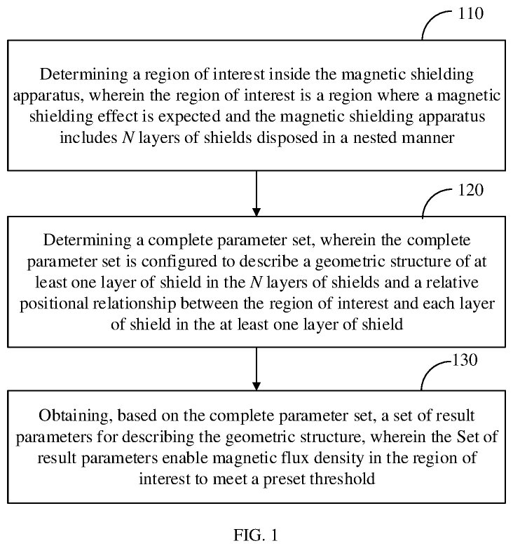

FIG. 1 shows a method for designing a magnetic shielding apparatus according to an exemplary embodiment of the present application, and the method may be performed by a computer device. The method includes:

110, determining a region of interest 2 inside the magnetic shielding apparatus, wherein the region of interest 2 is a region where a magnetic shielding effect is expected to be achieved, and the magnetic shielding apparatus includes N layers of shields disposed in a nested manner;

120, determining a complete parameter set, wherein the complete parameter set is used to describe a geometric structure of at least one layer of shield 1 in the N layers of shields 1 and a relative positional relationship between the region of interest 2 and each layer of shield 1 of the at least one layer of shield 1; and

130, obtaining, based on the complete parameter set, a set of result parameters for describing the geometric structure, wherein the result parameters enable magnetic flux density in the region of interest 2 to meet a preset threshold. The preset threshold of the magnetic flux density has a corresponding external magnetic flux density. For example, assuming that the magnetic shielding apparatus is exposed to a uniform axial magnetic flux density of 1000 nT, a maximum (or average) magnetic flux density in the region of interest 2 is not greater than 1 nT.

The method for designing a magnetic shielding apparatus provided in this embodiment uses the region of interest 2 in the magnetic shielding apparatus as a reference for the optimization design, which is different from that using a certain point as a reference for optimization design. In addition, the method is used to find a set of optimal combination of independent variables by using a plurality of independent variables based on complete parameters, which can minimize the magnetic flux density in the region of interest 2. This not only can optimize the design of the magnetic shielding apparatus, but may also help designers know which parameters in the complete parameter set can be modified by comparing the complete parameter set to further optimize performance of the magnetic shielding apparatus.

A general optimization problem may be transformed into a problem of finding a minimum value of a multivariate function. The multivariable function is referred to as an objective function. An independent variable of the objective function is referred to as a control variable, and there are a plurality of control variables. A combination of the control variables that makes the function obtain a minimum value is referred to as a minimizer of the function. Contribution of the objective function comes from two parts: one is the problem to be optimized, and the other is a penalty function.

For a problem of the minimum value of the multivariate function with a constraint, a penalty function method is used to transform the problem into a problem of the minimum value of the multivariate function without constraints. The penalty function has the following properties: when the control variable is far from a constraint boundary, a value of the penalty function is small; when the control variable is close to the constraint boundary, the value of the penalty function is large. As the penalty function is a part of the contribution of the objective function, in a process of finding the minimum value of the objective function, the control variable may keep a distance from the constraint boundary. In some optimization algorithms of iterative calculation, after each iteration, whether the constraints are violated is determined, and if yes, recalculation is performed by using a manner such as reducing a step size, until the constraints are not violated.

When the objective function is not differentiable with respect to the independent variable, calculation can be performed by means of a derivative-free optimization algorithm. Therefore, in an embodiment, the obtaining, based on the complete parameter set, a set of result parameters for describing the geometric structure includes: inputting the complete parameter set as independent variables and the magnetic flux density in the region of interest 2 as a dependent variable into a derivative-free optimization model to obtain a set of optimal parameters, wherein the independent variables include non-monotonically increasing independent variables, and the dependent variable does not increase monotonically when the non-monotonically increasing independent variables increase; and constants are set to define upper bounds of the non-monotonically increasing independent variables in the derivative-free optimization model. Specifically, the non-monotonically increasing independent variables satisfy the following conditions: as the independent variables increase, magnetic shielding performance does not increase monotonously, but starts to decrease after a certain point. Therefore, the constants can be used to define the upper bounds of the non-monotonically increasing independent variables. In addition, when the magnetic shielding performance is optimal, the non-monotonically increasing independent variables do not reach the upper bounds. The reason for adding the constants to define the upper bounds of the non-monotonically increasing variables is to set a search range of the derivative-free optimization algorithm. The independent variables in the present application further include monotonic independent variables, and the constants cannot be arbitrarily designated as their upper bounds. The monotonic independent variables satisfy the following condition: as the monotonic independent variables increase, the magnetic shielding performance monotonously increases. Therefore, after an optimization of the monotonic independent variables, there must be one or more independent variables that reach the upper bounds.

Verification is performed to determine whether the non-monotonically increasing independent variables in the optimal parameters reach the upper bounds defined by the constants. If yes, the constants of the derivative-free optimization model are increased and then the derivative-free optimization model is recalculated; if no, verification is performed to determine whether the magnetic flux density in the region of interest 2 of the magnetic shielding apparatus with the optimal parameters meets the preset threshold. If yes, results are output, and the results output are result parameters; if no, an input of the derivative-free optimization model is adjusted, and then the derivative-free optimization model is recalculated.

In an embodiment, the input of the derivative-free optimization model in the adjusting an input of the derivative-free optimization model includes: the constraints, a number of times of repeated calculations or a termination condition of an iterative calculation, and a parameter type and a parameter range of the complete parameter set. Adjustment of the parameter type and the parameter range of the complete parameter set may be implemented by adjusting any one or more of a thickness of material of the magnetic shielding apparatus, a quantity of layers of shields 1, and a basic geometric structure of the magnetic shielding apparatus. The “basic geometric structure” refers to a structural category of the shield structure, such as cylinder, cuboid, or the like, while the “geometric structure” mentioned above refers to a specific structure of the shield, and the specific structure is one type of the basic geometric structure. The geometric structure is defined by specific parameters such as a height and a radius of a cylinder; a length, a width, and a height of a rectangular solid; and the like.

In an embodiment, the inputting these variables into a derivative-free optimization model to obtain a set of optimal parameters includes: obtaining optimization parameters based on the complete parameter set through calculation of the derivative-free optimization model, converting the optimization parameters into the magnetic flux density by using a method for obtaining magnetic field distribution of the magnetic shielding apparatus from the geometric structure, and obtaining the optimal parameters and the magnetic flux density in the region of interest 2 of the magnetic shielding apparatus with the optimal parameters by using repeated calculation or iterative calculation during calculation of the derivative-free optimization model. In an embodiment, the using repeated calculation during calculation of the derivative-free optimization model includes: during calculation of the derivative-free optimization model, calculating objective function values corresponding to all parameter combinations according to a rule of the repeated calculation, selecting optimal parameters corresponding to a minimum objective function value, and obtaining the value and a corresponding magnetic flux density in the region of interest of the magnetic shielding apparatus with the optimal parameters. The using iterative calculation during calculation of the derivative-free optimization model includes: during calculation of the derivative-free optimization model, obtaining new optimization parameters based on values of parameters to be optimized and a corresponding objective function value used in previous calculation, and performing calculation continuously according to an iteration termination condition until the optimal parameters and the magnetic flux density in the region of interest of the magnetic shielding apparatus with the optimal parameters are obtained.

Specifically, the optimal parameters are the parameters obtained in the last iteration of the iterative calculation, or the parameters that minimizes the objective function value during the repeated calculation. The derivative-free optimization model calls a method of obtaining the magnetic field distribution of the magnetic shielding apparatus from the geometric structure, and uses the method to obtain, based on the optimal parameters, the magnetic flux density in the region of interest 2 of the magnetic shielding apparatus with the optimal parameters. Finally, the derivative-free optimization model outputs the optimal parameters and the magnetic flux density in the region of interest 2 of the magnetic shielding apparatus with the optimal parameters.

A specific calculation about the repeated calculation or iterative calculation includes the following steps.

The iterative calculation is applicable to a case that the derivative-free optimization algorithm determines, depending on an input of an objective function value, values of parameters to be optimized selected for a next calculation. An implementation of a coordinate search algorithm is used as an example. Firstly, the implementation is described in detail: there are n control variables in the algorithm, and an optimization step length is δ. For the i^{th} variable uᵢ, (uᵢ−δ) and (uᵢ+δ) are used as coordinates of test points and the objective function values are calculated. In this way, objective function values of 2n test points are calculated. In addition, an objective function value at an initial value is calculated or an objective function value at a previous iteration is obtained. In the (2n+1) values, if the objective function value at the initial value or the previous iteration is the smallest, the foregoing steps are repeated after the optimization step length is reduced; if the objective function value of a certain test point is the smallest, this point is set as a new initial value point and the foregoing steps are repeated. Iteration is performed until a minimum value is found.

A condition for termination of the iteration needs to be set in advance. In order to determine when to terminate the iteration, an optimization tolerance τ needs to be set. A manner of terminating iteration by using optimization tolerance varies depending on the algorithm. For the foregoing coordinate search method, after each iteration, a range of the foregoing (2n+1) values is calculated. When the range is less than the optimization tolerance τ, the iteration is terminated.

The repeated calculation is applicable to a case that a derivative-free optimization algorithm selected by the derivative-free optimization model determines, independent of an input objective function value, values of parameters to be optimized selected for a next calculation, for example, an exhaustive search method. Specifically, the exhaustive search method exhausts all parameter combinations with a preset precision and range. After all calculations are completed, a parameter value combination with the smallest objective function is selected as the output.

All the foregoing calculation methods can be implemented by using conventional software. For example, the fminsearch function of MATLAB can automatically perform derivative-free optimization, and algorithm source code of other algorithms based on MATLAB, Python, C, and other languages is also easy to implement.

In an embodiment, the method for obtaining magnetic field distribution of the magnetic shielding apparatus from the geometric structure includes a finite element method. Specifically, the finite element method is called by the derivative-free optimization model and optimal parameters obtained by the derivative-free optimization model is input to obtain the magnetic flux density in the region of interest 2 of the magnetic shielding apparatus with the optimal parameters, and finally the derivative-free optimization model outputs the optimal parameters and the magnetic flux density in the region of interest 2 of the magnetic shielding apparatus with the optimal parameters. The magnetic flux density is compared with a preset threshold, and this operation can be performed manually or by using a software program.

In another embodiment, the method for obtaining the magnetic field distribution of the magnetic shielding apparatus from the geometric structure is not limited to the finite element method, and a boundary element method and the finite element method can be used together to resolve the problem.

In an embodiment, basic geometric structures of N layers of shields are the same and all have symmetry, and the region of interest 2 is a three-dimensional space. Based on a large amount of fact and experience, it can be learned that the better the symmetry of the magnetic shielding apparatus is, the better the performance of the magnetic shielding apparatus may be. Therefore, according to the method in this embodiment, other parameters of the magnetic shielding apparatus are optimized based on a fact that a geometric structure of the magnetic shielding apparatus has symmetry. And a three-dimensional space is selected as the region of interest 2 to make the method more scientific.

In an embodiment, a center of the region of interest 2 is on the axis of symmetry of the N layers of shields 1, that is, the center of the region of interest 2 is on the axis of symmetry of the magnetic shielding apparatus. Either of the following two methods may be used to determine the center of the region of interest 2. Manner 1: the geometric center of the magnetic shielding apparatus, namely, the center of mass, is used as the center of the region of interest 2. Manner 2: a midpoint of a line connecting two points furthest apart in an axial direction of the magnetic shielding apparatus may be selected as the center of the region of interest 2.

To further reduce the quantity of parameters in the complete parameter set and then improve calculation efficiency of the method, in an embodiment, the region of interest 2 has axial symmetry, and the axis of symmetry of the region of interest 2 coincides with the axis of symmetry of the N layers of shields 1, that is, the axis of symmetry of the region of interest 2 coincides with the axis of symmetry of the magnetic shielding apparatus. In another embodiment, the region of interest 2 is a cylindrical region. However, the region of interest 2 is not limited to be in a cylindrical shape. Any region with axial symmetry is acceptable, such as regions in a spindle shape, a spherical shape, and the like. If an original region of interest 2 does not satisfy axial symmetry or the axis of symmetry does not coincide with the axis of symmetry of the magnetic shielding apparatus, the original region of interest 2 should be expanded to obtain a new region of interest 2, so that the new region of interest 2 becomes a smallest axisymmetric structure that can contain the original region of interest 2, and its axis of symmetry coincides with the axis of symmetry of the magnetic shielding apparatus. The axial symmetry makes it possible to completely describe the geometric structure by selecting only geometric parameters on the symmetrical section during selection of the complete parameter set. Therefore, the quantity of parameters in the complete parameter set is reduced, and the calculation efficiency of the method is improved.

The parameters included in the complete parameter set are parameters of the geometric structure that can control all possible manners of varying of the geometric structure. For different geometric structures, the complete parameter set includes different parameters for describing its geometric structure. For example, for a single spherical shield and a spherical region of interest in the spherical shield, the complete parameter set includes four parameters, namely an inner radius (or outer radius) of the spherical shield, displacement vectors in three directions of the center of the region of interest relative to the center of the spherical shield. Herein the displacement vectors in three directions cannot be replaced by a distance between the two sphere centers, because when the two sphere centers do not coincide, the shielding performance of the apparatus is anisotropic, while an external magnetic field is vectorial, so that a relative position relationship of the two sphere centers in the three-dimensional space needs to be clarified. For example, for a single cuboid shield and a cuboid region of interest inside the cuboid shield, the complete parameter set includes six parameters, namely a length, width, and height (inside or outside) of the cuboid shield, displacement vectors in three directions of a vertex of the region of interest relative to a vertex of the cuboid shield. Therefore, in order to be able to describe all possible variants of the cylindrical magnetic shield based on the geometric structure, the complete parameter set is determined based on basic parameters of the magnetic shielding apparatus in this embodiment. Specifically, in an embodiment, the determining the complete parameter set includes: determining the basic parameters of the magnetic shielding apparatus according to the preset threshold of magnetic flux density of the region of interest 2; and determining the complete parameter set according to the basic parameters, wherein the basic parameters include parameters used to represent a basic geometric structure of the magnetic shielding apparatus, a quantity of layers of shields 1 included by the magnetic shielding apparatus, materials of the N layers of shields 1, a thickness of each layer of shield 1, a size of the region of interest 2, and a position of the region of interest 2 relative to the magnetic shielding apparatus. The foregoing “parameter used to represent a basic geometric structure of the magnetic shielding apparatus” specifically refers to types of the parameters for representing the geometric structure of the magnetic shielding apparatus. Specifically, an example of the method for determining the basic parameters of the magnetic shielding apparatus according to the preset threshold of magnetic flux density of the region of interest 2 is as follows: the preset threshold is that, when a background magnetic field is 1000 nT, an average magnetic flux density norm in the region of interest is expected to be not more than 100 nT. Based on this threshold, it can be estimated that a quantity of layers does not need to be greater than 4.

To improve the calculation efficiency, in a further embodiment, the obtaining, based on the complete parameter set, a set of result parameters for describing the geometric structure includes: determining constraints; and obtaining, based on the constraints and the complete parameter set, the set of result parameters for describing the geometric structure, wherein the constraints limit a range of parameters in the complete parameter set. The constraint is an inequality. When monotonic independent variables are restricted by the constraints, the corresponding constraint may be converted from an inequality to an equation to reduce the quantity of parameters in the complete parameter set, thereby improving the calculation efficiency of the derivative-free optimization model.

To improve the calculation efficiency of the derivative-free optimization model, in an embodiment, the method further includes: selecting, based on the complete parameter set, independent parameters having the same quantity of parameters as the complete parameter set, wherein the independent parameters have the same completeness as the complete parameter set and are used to completely describe the geometric structure; constructing first-level generalized coordinates based on the independent parameters; and in the first-level generalized coordinates, obtaining, based on the complete parameter set, parameters that describe differential characteristics of the geometric structure in the first-level generalized coordinates. The first-level generalized coordinates are formed by selecting, based on the complete parameter set, a differential feature in the geometric structure of the magnetic shielding apparatus. This is because an optimization algorithm in the derivative-free optimization model attempts to change a feature of the geometric structure, while an amount of changes is small relative to a reference amount, for example, an amount of change in a radius of a bottom surface is much smaller than the radius itself, which is not favorable to operation of most optimization algorithms. The selection of the difference feature in the geometric structure of the magnetic shielding apparatus is beneficial to improving the calculation efficiency of the derivative-free optimization model, thereby improving the calculation efficiency of the entire method.

To further improve the calculation efficiency of the derivative-free optimization model, in an embodiment, second-level generalized coordinates are constructed based on the first-level generalized coordinates; and the first-level generalized coordinates are normalized by using the second-level generalized coordinates. Normalization brings parameters to be optimized in the complete parameter set near a high-dimensional unit sphere in a parameter space, which is beneficial to improving the calculation efficiency of the derivative-free optimization model.

In an embodiment, the basic geometric structure of the magnetic shielding apparatus is a geometric structure provided with at least one opening, and centers of the basic geometric structures of the N layers of shields 1 do not coincide with each other, wherein the opening connects the region of interest 2 with outer space of the N layers of shields. In another embodiment, the magnetic shielding apparatus is a non-concentric geometric structure provided with one opening. A conventional analytical method cannot be used to calculate a shielding factor of a magnetic shielding apparatus with a non-concentric structure and an opening. However, according to the method provided in this embodiment, a finite element model is used for numerical calculation, which can accurately calculate the magnetic shielding apparatus with a non-concentric structure and an opening. In addition, accuracy of the method in this embodiment can be adjusted. A numerical method is not absolutely accurate, and its accuracy is influenced by numerical accuracy of a computer, density of a finite element mesh, and a tolerance solution of a system of linear equations. Therefore, calculation accuracy of the numerical method can be adjusted by adjusting the foregoing parameters. For example, the calculation accuracy of the numerical method can be improved by appropriately refining the finite element mesh and reducing the tolerance of a solver for the system of linear equations.

From a perspective of increasing adaptability of the magnetic shielding apparatus, improving its magnetic shielding performance, and appropriately reducing processing difficulties and costs, in an embodiment, the basic geometric structure of the magnetic shielding apparatus is a cylindrical structure with cylindrical symmetry and a single end open, a ring structure 5 extending in a direction from an outer edge of the shield to an axis of symmetry of the cylindrical structure is provided at an opening of at least one layer of shield 1 in the N layers of shields 1, and the ring structure 5 shields a gap, perpendicular to a direction of the axis of symmetry, between adjacent shields 1; and the complete parameter set is used to represent a parameter of a symmetrical section 6 of the cylindrical structure, where the symmetrical section 6 refers to a half-plane passing through the axis of symmetry and using the axis of symmetry as a boundary.

In another embodiment, the ring structure 5 is provided at an opening of each of N−1 layers of shields, in the N layers of shields 1, except an innermost layer of shield. The ring structure 5 can improve the shielding performance without changing a size of an internal space and an external size. The ring structure 5 is not added to the innermost layer, so that a size of the opening of the magnetic shielding apparatus is not reduced, thereby not reducing a maximum size of an object that can enter the internal space.

Based on the foregoing structure, for example, the parameters in the complete parameter set for describing the geometric structure of the magnetic shielding apparatus include a radius Rᵢ of a bottom surface of the cylindrical structure, an axial distance L_{Ai} from the bottom surface to the center of the region of interest, an axial distance L_{Bi} from each layer of shield in the N layers of shields to the center of the region of interest, and a width Cᵢ of the ring structure, wherein i denotes the i^{th} layer of shield, wherein

when each layer of shield in the N layers of shields is provided with the ring structure, L_{Bi} is an axial distance from a geometric center, namely, the center of mass, of the ring structure to the center of the region of interest; and

when at least one layer of shield in the N layers of shields is not provided with the ring structure, for the shield not provided with the ring structure, L_{Bi} is an axial distance from an outer edge of the corresponding shield not provided with the ring structure to the center of the region of interest; and for the shield, in the N layers of shields, provided with the ring structure, L_{Bi} is an axial distance from a geometric center, namely, the center of mass, of the ring structure to the center of the region of interest.

In an embodiment, range limits are imposed on the parameters in the complete parameter set by constraints, wherein the constraints include: an outer-size constraint, an inner-size constraint, a minimum-width constraint, and a region-of-interest constraint. The outer-size constraint is used to define a maximum outer boundary of the magnetic shielding apparatus; the inner-size constraint is used to define a minimum internal space of the magnetic shielding apparatus; the spacing constraint is used to define a minimum spacing between adjacent shields; the minimum-width constraint is used to define a minimum width of the ring structure 5; and the region-of-interest constraint is used to define a minimum axial distance from the region of interest 2 to a bottom surface of the innermost layer of shield of the magnetic shielding apparatus.

In another embodiment, the constraints further include an additional constraint, and the additional constraint is used to limit a radius difference of outer layers of adjacent shields to be greater than that of inner layers of the adjacent shields, that is, Rᵢ₊₁−Rᵢ>Rᵢ−Rᵢ₋₁.

The method for designing a magnetic shielding apparatus provided in this embodiment uses a combination of the derivative-free optimization model and finite element analysis. This not only makes the magnetic shielding performance of an optimized magnetic shielding apparatus greatly improved compared with that of a magnetic shielding apparatus using a solution of equal spacing between shields, but also resolves a problem that the analytical method cannot be used to optimize a magnetic shielding apparatus with a non-concentric structure. In addition, a derivative-free optimization method is used in this method, which makes calculation more efficient, and enables a large quantity of parameters to be tried. The complete parameter set is used to control all possible variants based on the geometric structure, and a fixed process is used to perform the optimization design, so as to reduce a subjective influence of people, thereby obtaining more scientific data results. It should be noted that this method is not limited to be implemented by combining the derivative-free optimization model and the finite element method. It can also be implemented by combining the derivative-free optimization model and hybrid of the finite element method and the boundary element method, or by replacing the derivative-free optimization model in the present application with methods such as model training, machine learning, and the like, and design of the magnetic shielding apparatus is optimized based on the inventive concept of the present application.

To better demonstrate the inventive concept of the present application, based on the foregoing exemplary method, another exemplary embodiment is provided to further illustrate the method for designing a magnetic shielding apparatus in the present application. This exemplary embodiment uses an example in which a quantity of layers of shields 1 of the magnetic shielding apparatus is 6. However, an actual quantity of layers is not limited to 6.

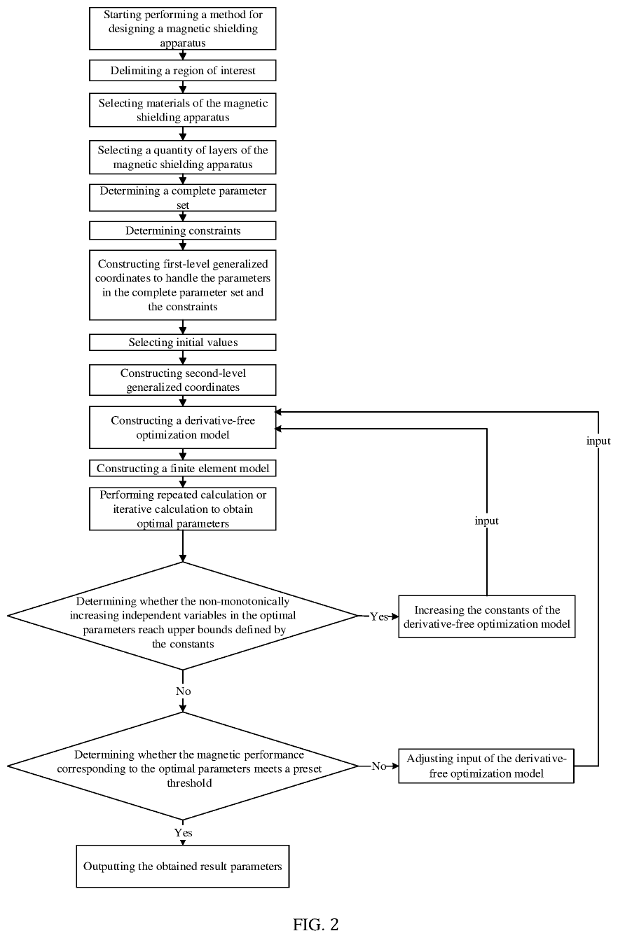

As shown in FIG. 2, this exemplary embodiment provides a method for designing a cylindrical magnetic shielding apparatus with a single end open and a plurality of layers nested. A basic geometric structure of the magnetic shielding apparatus is a cylindrical magnetic shield with an open end and a plurality of layers nested. A direction along a radius of a bottom surface of the cylinder is defined as a radial direction, and a direction along the height of the cylinder is defined as an axial direction. The open end is referred to as an open end 3, and the other end closed and disposed opposite to the open end 3 is a closed end 4.

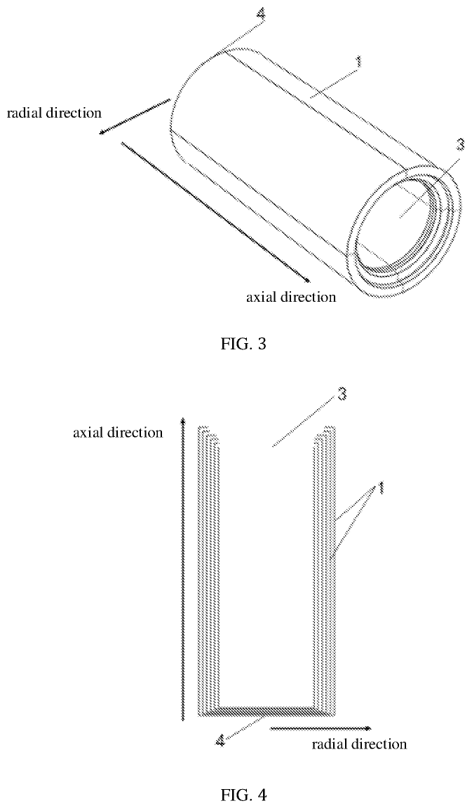

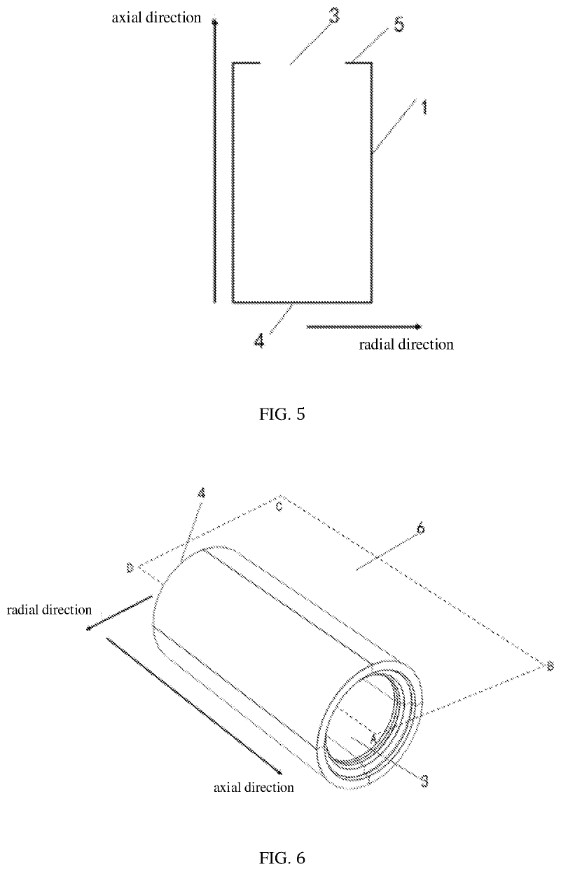

A three-dimensional view of a cylindrical magnetic shield to be optimized is shown in FIG. 3. The radial direction is not limited to the illustrated direction, and any direction parallel to the radius of the bottom surface of the cylinder may be regarded as the radial direction. A two-dimensional cross-sectional view of the cylindrical magnetic shield to be optimized is shown in FIG. 4. The section may be selected as any plane that passes through both an axis of symmetry of the cylinder and a diameter of the bottom surface. The cylindrical magnetic shield is composed of a plurality of layers of shields 1 nested together. A structure of each layer of shield 1 is shown in FIG. 5, and structures of the plurality of layers of shields 1 nested together are shown in FIG. 3 and FIG. 4.

A ring structure 5 extending in a direction from an outer edge of the shield 1 to an axis of symmetry is provided at an opening of each layer of shield 1, and the ring structure 5 is not added to an opening of the innermost layer of shield. The ring structure 5 can improve the shielding performance without changing a size of an internal space and an external size of the cylindrical magnetic shield. The ring structure 5 is not added to the opening of the innermost layer, so as to avoid a case that an aperture of the opening of the cylindrical magnetic shield is reduced, thereby avoiding reducing a maximum size of an object that can enter the internal space of the cylindrical magnetic shield.

The structure of the cylindrical magnetic shield in this embodiment has rotational symmetry. Therefore, the geometric structure of the entire apparatus may be completely described by selecting only a set of parameters to describe the geometric structure on a symmetrical section 6.

The symmetrical section 6 may be any half-plane that extends infinitely in other three directions while taking an axis of symmetry of the cylinder as one side. As shown in FIG. 6, in the three-dimensional view, the dashed frame ABCD denotes the symmetrical section 6, which is a half-plane. AD is an axis of symmetry of the cylinder, which is a straight line extending infinitely at both ends. BC is an infinitely extending straight line parallel to AD. AB is a ray with A as the end point, and the ray extends infinitely along AB in one direction and is parallel to a certain radius of the cylinder. DC is a ray parallel to AB, D is the end point of the ray, and the ray extends infinitely along DC in one direction. The foregoing certain radius may be any radius, so that a position of the symmetrical section 6 is not limited to the one shown in the figure, and may alternatively be a position obtained after the symmetrical section 6 is arbitrarily rotated around the axis of symmetry AD.

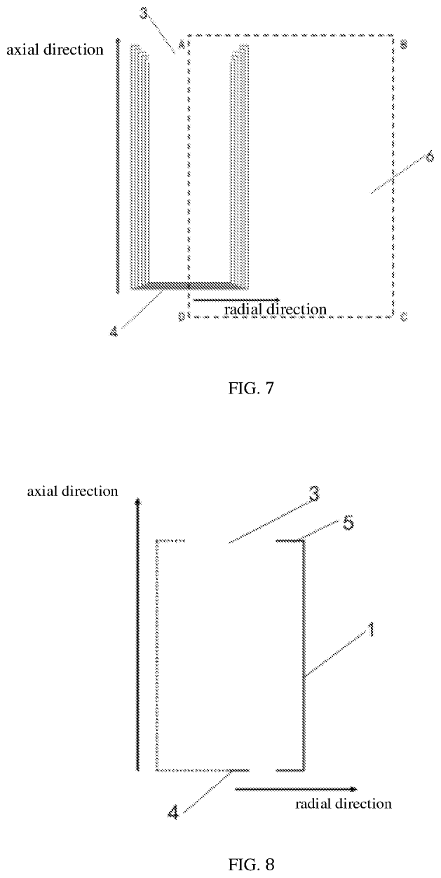

As shown in FIG. 7, in the two-dimensional view, the dashed frame ABCD denotes the symmetrical section 6, which is a half-plane. AD is an axis of symmetry of the cylinder, which is a straight line extending infinitely at both ends. BC is an infinitely extending straight line parallel to AD. AB is a ray with A as the end point, and the ray extends infinitely along AB in one direction and is parallel to a certain radius of the cylinder. DC is a ray parallel to AB, D is the end point of the ray, and the ray extends infinitely along DC in one direction. Since a cross-section of the two-dimensional cross-sectional view can be selected as any plane that passes through both the axis of symmetry of the cylinder and a diameter of a bottom surface, the symmetrical section 6 may be at any position obtained after the symmetrical section 6 is arbitrarily rotated around the axis of symmetry AD.

As shown in FIG. 8, for a structure of each layer of shield 1, in the symmetrical section 6, only the part in solid line in the figure is useful, and the part in dotted line is outside the symmetrical section 6 and is not considered.

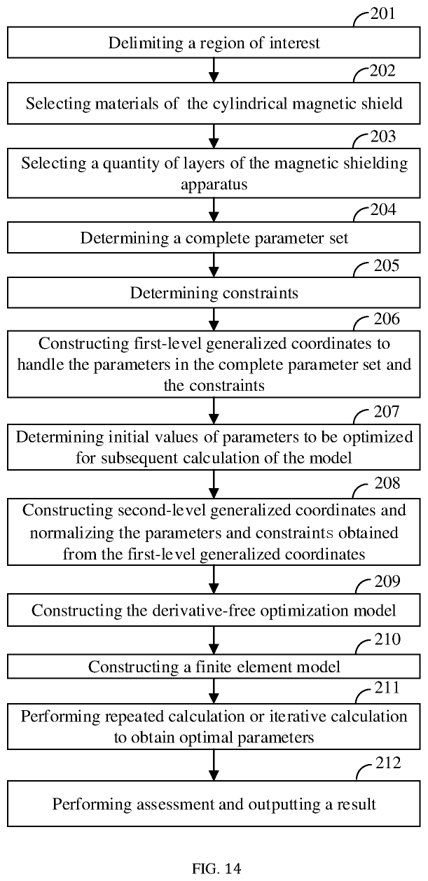

In an embodiment, a method for designing a cylindrical magnetic shield with a single end open and a plurality of layers nested is provided. FIG. 14 is a schematic flowchart of the method for designing a cylindrical magnetic shield with a single end open and a plurality of layers nested. This method can be performed by using a calculation program or a software product. As shown in FIG. 14, a specific operation process of this method includes the following steps.

201: delimiting a region of interest.

As shown in FIG. 8, the region of interest 2 is inside the cylindrical magnetic shield and is a region where a magnetic shielding effect is expected to be achieved.

The region of interest 2 is a region in a three-dimensional space, which has axial symmetry and the axis of symmetry coincides with an axis of symmetry of the cylindrical magnetic shield. In an embodiment, the region of interest 2 is a cylindrical region. However, the region of interest 2 is not limited to be in a cylindrical shape. Any region with axial symmetry is acceptable, such as regions in a spindle shape, a spherical shape, and the like.

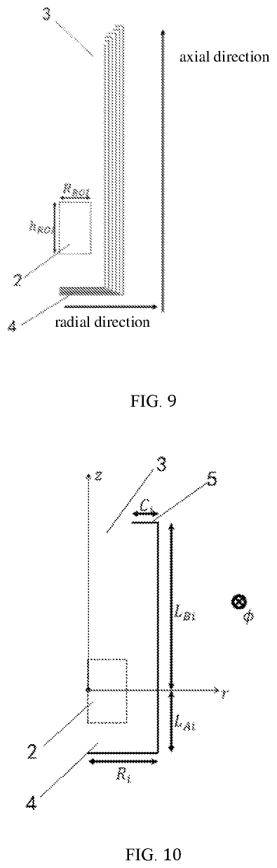

For example, a cylindrical region of interest 2 is selected. The cylindrical shape can be completely described by a radius R_{ROI} of a bottom surface and a height h_{ROI}. Thus, the volume of the region of interest 2 is V_{ROI}=πR_{ROI}²h_{ROI}. For a region of interest 2 in another shape, corresponding parameters should be selected for complete description and volume calculation. In a symmetrical section 6, the cylindrical region of interest 2 becomes a rectangle. As shown in FIG. 9, the rectangle drawn with a dotted line is the region of interest 2. The width of the rectangle corresponds to the radius R_{ROI} of the bottom surface of the cylindrical region of interest 2, and the height of the rectangle corresponds to the height h_{ROI} of the cylindrical region of interest 2. ROI is an abbreviation of region of interest, which denotes the region of interest 2.

In this example, R_{ROI}=200 mm; and

h_{ROI}=400 mm.

202: selecting materials of the cylindrical magnetic shield.

There are many types of magnetic materials, such as a soft magnetic alloy, a hard magnetic alloy, a soft magnetic ferrite, and an amorphous magnetic material. A soft magnetic material (including alloys and ferrites) has the following characteristics. In an external magnetic field, its internal magnetic flux density is relatively large; however, when the external magnetic field is removed, its internal magnetic flux density is relatively small and almost restored to an initial state, such as permalloy. A hard magnetic material has the following characteristics. In the external magnetic field, its internal magnetic flux density is relatively large; however, when the external magnetic field is removed, its internal magnetic flux density is still large and cannot be restored to a state close to an initial state without external intervention, such as a permanent magnet (magnet). An alloy generally has good machinability and mechanical properties, and is easy to be manufactured to a medium-large magnetic shielding apparatus. In contrast, a ferrite is obtained by sintering ceramics, and is not easy to process and has poor mechanical properties. The ferrite can be used to manufacture only a small magnetic shielding apparatus. Generally, an amorphous magnetic material can only be used to manufacture a foil, and cannot be used as a major structure of the magnetic shielding apparatus, but can be used only as an accessory structure.

In an embodiment, the material of the cylindrical magnetic shield may be high permeability permalloy. However, the selection is not limited to permalloy. Other materials such as iron, silicon steel, ferrite, and other nickel steel alloys can also be selected. Particularly, a combination of a plurality of materials can be selected. For example, an innermost layer of a multilayer permalloy cylindrical magnetic shield can use ferrite instead of permalloy, which can greatly reduce thermal noise at the expense of a small amount of shielding performance, because a conductivity of ferrite is lower than that of permalloy.

Once the material to be used is determined, a magnetic property of the material should be obtained. In an embodiment, initial permeability μ or initial relative permeability μᵣ of the material can be obtained. Alternatively, an initial B-H or H-B curve (also referred to as an initial magnetization curve) of the material can be obtained. Before the cylindrical magnetic shield is processed, the data cannot be accurately determined, because the final step of overall annealing will change a magnetic property of the material. However, performance of a material of the same model is relatively stable, and data of a plurality of batches of materials before processing should be obtained as required data. In addition, a material thickness d needs to be determined. Material thickness can be different for each layer depending on specifications that a material supplier can provide, the shielding performance, and mechanical properties.

In this embodiment, for example, 1J85 permalloy is selected, and based on a plurality of batches of data, an initial relative permeability is obtained, μᵣ=30000, and d=1.5 mm.

203: selecting a quantity of layers of the cylindrical magnetic shield.

The quantity of layers of the cylindrical magnetic shield should be estimated based on a size and a position of the region of interest 2, expected shielding performance, and a material performance. A quantity of layers of a common cylindrical magnetic shield ranges from 2 to 8, but the present application does not impose a limitation to these layers. Only when the quantity of layers is selected, can the following steps of this method be performed. In subsequent steps, the shielding performance is calculated. If performance of an optimized magnetic shielding apparatus cannot meet a preset threshold, there is a need to return to this step and select for more layers. If the performance of the optimized magnetic shielding apparatus far exceeds the preset threshold, it can be chosen to return to this step and reselect for fewer layers to reduce costs. An innermost layer is defined as the first layer, and the number increases outwards layer by layer.

In this example, six layers are selected.

204: determining a complete parameter set.

Regarding how to determine the complete parameter set, in an embodiment, to determine parameter coordinates, a coordinate system needs to be established. Specifically, a two-dimensional plane coordinate system is established in the symmetrical section 6 of the magnetic shielding apparatus. In an embodiment, a two-dimensional Cartesian coordinate system is used. An origin of the coordinate system is located at a midpoint of a structure wherein the axis of symmetry of the region of interest 2 is located, a first coordinate axis (named r axis) is in the radial direction, and a second coordinate axis (named z axis) is in the axial direction. When the symmetrical section 6 is placed in a three-dimensional view, a third axis (named ϕ axis) can be added to form a cylindrical coordinate system in a three-dimensional space. In a two-dimensional cross-sectional view, the third axis is perpendicular to a paper surface outward.

FIG. 10 shows a complete parameter set required to describe a structure of a single layer (the i^{th} layer) and a region of interest 2. The complete parameter set includes four parameters in total as follows:

i. a radius Rᵢ of a bottom surface;

ii. an axial distance L_{Ai} between the bottom surface and the center of the region of interest 2;

iii. an axial distance L_{Bi} between a ring structure 5 at an open end 3 and the center of the region of interest 2; and

iv. a width Cᵢ of the ring structure 5 at the open end 3.

Generally, for a cylindrical magnetic shield with N layers and a single end open, 4N parameters are required to form the complete parameter set. When there is no ring structure 5 in the innermost layer, Cᵢ is removed, and (4N−1) parameters are required to form the complete parameter set. For example, in a case that N=6 and there is no ring structure 5 in the innermost layer, 23 parameters are required to form the complete parameter set. The 23 parameters are

R₁, R₂, R₃, R₄, R₅, R₆, L_{A1}, L_{A2}, L_{A3}, L_{A4}, L_{A5}, L_{A6}, L_{B1}, L_{B2}, L_{B3}, L_{B4},

L_{B5}, L_{B6}, C₂, C₃, C₄, C₅, C₆.

205: determining constraints.

The constraints include the following six categories.

i. An outer-size constraint, which involves a maximum length Lₘₐₓ and a maximum width DIAₘₐₓ of the cylindrical magnetic shield, and is used to define a maximum outer boundary of the cylindrical magnetic shield to ensure that a volume of the cylindrical magnetic shield is within a reasonable range. This needs to be determined by referring to an environment in which the cylindrical magnetic shield is used, such as a passing capacity of a corridor of a building, a freight elevator, a door, and the like, and an available space of a room which is determined after deducting an external additional shield and parts. A method of the constraint acting on the parameters is as follows:

L_{AN}+L_{BN}≤Lₘₐₓ

2R_{N}≤DIAₘₐₓ

In an embodiment, the first equation is strengthened to equality, that is, L_{BN}=Lₘₐₓ−L_{AN}

This is because, in a typical application range, the shielding performance of a cylindrical magnetic shield with a single end open generally becomes greater as a length increases. Adding of the equality constraint can reduce the quantity of parameters in the complete parameter set, thus reducing a quantity of parameters to be optimized in the complete parameter set, so as to improve overall calculation efficiency.

The typical applicable range means that a ratio of an axial length of each layer to a diameter of a bottom surface is between 0 and 2. This value may change slightly with addition of the ring structure 5. In this example, Lₘₐₓ=2179 mm and DIAₘₐₓ=1258 mm are selected.

ii. An inner-size constraint, which involves a minimum inner width DIAₘᵢₙ of the cylindrical magnetic shield, and is used to define a minimum internal space of the cylindrical magnetic shield to ensure that an opening has a diameter large enough to allow a shielded body to pass through and accommodate. This needs to be determined by referring to a maximum size of the shielded body after adding an additional internal shield and parts. Since the cylindrical magnetic shield is open at a single end, there is no need to consider a minimum length constraint.

A method of the inner-size constraint acting on the parameters is as follows:
2R₁≥DIAₘᵢₙ
2(Rᵢ−Cᵢ)≥DIAₘᵢₙ

In an embodiment, the first equation is strengthened to equality, that is, R₁=DIAₘᵢₙ/2.

This is because, in a typical application range, the shielding performance of the cylindrical magnetic shield with a single end open generally becomes greater as the radius decreases. Adding the equality constraint can reduce the quantity of parameters in the complete parameter set, thus reducing a quantity of parameters to be optimized in the complete parameter set in step 206, so as to improve the overall calculation efficiency in step 211. If the ring structure 5 is added to an innermost layer, the first equation cannot be used. In this example, the ring structure 5 is not added to the innermost layer, and DIAₘᵢₙ=722 mm is selected.

iii. A spacing constraint, which involves a minimum spacing G, and is used to define a minimum spacing between adjacent shields 1 to ensure that there is enough space to arrange an interlayer degaussing cable during assembly, and to be filled with a shock-absorbing and supporting material. This requires that a diameter of the interlayer degaussing cable and assembly process are taken into consideration. A method of the constraint acting on the parameters is as follows:
Rᵢ₊₁−Rᵢ≥G
L_{A(i+1)}−L_{Ai}≥G
L_{B(i+1)}−L_{Bi}≥G

In this example, G=10 mm is selected.

iv. A minimum-width constraint, which involves a minimum width W, and is used to define a minimum width of the ring structure 5. When a width of the ring structure 5 is less than the minimum width, the ring structure 5 cannot be processed. A method of the constraint acting on the parameters is as follows:
Cᵢ≥W

In this example, W=10 mm is selected.

v. A region-of-interest constraint, which involves a minimum distance F from a boundary of the region of interest 2 in the axial direction to a bottom surface of an innermost layer of the cylindrical magnetic shield, and is used to define a minimum axial distance from the region of interest 2 to the bottom surface of the innermost layer of the cylindrical magnetic shield. Determination of the minimum axial distance is related to demagnetization. In an ideal demagnetization case, F=0. Since there is no remanence in the innermost layer of the cylindrical magnetic shield, the region of interest 2 is not affected. Generally, in a better demagnetization case, when F=1500 mm is selected, an impact of the remanence in the innermost layer of the cylindrical magnetic shield on the region of interest 2 can be reduced to a negligible extent. Particularly, if the shielded body itself generates a magnetic field, F needs to be increased appropriately to reduce a coupling effect with the innermost layer of the cylindrical magnetic shield and magnetization of the innermost layer of the cylindrical magnetic shield. A method of the constraint acting on the parameters is as follows:
L_{A1}−LA_{ROI}≥F

wherein LA_{ROI} denotes a maximum distance from the center of the region of interest 2 to a boundary, near the bottom surface of the innermost layer of the cylindrical magnetic shield, of the region of interest 2.

In this example, F=1500 mm is selected. Since the region of interest 2 is a cylinder, LA_{ROI}=h_{ROI}/2.

vi. An additional constraint (optional), which is used to limit a radius difference of outer layers of shield 1 to be greater than that of inner layers of shield 1, to improve the calculation efficiency. This is because the shielding performance can be improved when an outer layer of shield 1 uses a larger radius difference. A method of the constraint acting on the parameters is as follows: Rᵢ₊₂−Rᵢ₊₁≥Rᵢ₊₁−Rᵢ.

This additional constraint is added in this example.

206: constructing first-level generalized coordinates to handle the parameters in the complete parameter set and the constraints.

In a case that the ring structure 5 is not added to the innermost layer of shield and R₁=DIAₘᵢₙ/2; L_{BN} Lₘₐₓ−L_{AN}, there are (4N−3) independent parameters in the complete parameter set. Another (4N−3) independent parameters with the same completeness as the original parameter set are selected to completely describe the geometric structure. These (4N−3) independent parameters are referred to as generalized coordinates. The generalized coordinates are selected to improve the calculation efficiency.

The first-level generalized coordinates are formed by selecting, based on the complete parameter set, a differential feature in the geometric structure. This is because an optimization algorithm of the derivative-free optimization model used in this method tries to change a feature of the geometric structure, while an amount of change is small relative to a reference amount, for example, an amount of change in a radius of a bottom surface is much smaller than the radius itself, which is not favorable to operation of most optimization algorithms. Selection of the differential feature in the geometric structure is beneficial to improving the calculation efficiency of the derivative-free optimization model.

A radius difference is selected as follows:

R_{i_i+1}=Rᵢ₊₁−Rᵢ

which is used to replace the original Rᵢ₊₁.

A distance between adjacent bottom surfaces is selected as follows:

D_{i_i+1}=L_{A(i+1)}−L_{Ai}

which is used to replace an original axial distance L_{A(i+1)} between the bottom surface and the center of the region of interest 2.

An increase of a difference between the axial distance from the bottom surface of the innermost layer of shield of the cylindrical magnetic shield to the center of the region of interest 2 and the distance from the center of the region of interest 2 to an edge of the region of interest 2 closest to the bottom surface of the innermost layer of shield of the cylindrical magnetic shield relative to the minimum distance F from the boundary of the region of interest 2 to the bottom surface of the innermost layer of shield of the cylindrical magnetic shield is selected as follows:

L_{A1P}=L_{A1}−LA_{ROI}−F

which is used to replace the original L_{A1}.

A decrease value of the axial distance L_{Bi} between the ring structure 5 and the center of the region of interest 2 relative to the axial distance L_{BN} between the outermost ring structure 5 and the center of the region of interest 2 is selected as follows:

DLᵢ=L_{BN}−L_{Bi}

which is used to replace an original axial distance L_{Bi} between the ring structure 5 and the center of the region of interest 2. (It should be noted that L_{BN}=Lₘₐₓ−L_{AN}, and L_{AN} has been replaced by D_{N-1_N} L_{AN}−L_{A(N-1)}.)

According to the inner-size constraint, a maximum width allowed by the i^{th} layer of ring structure 5 is Rᵢ−DIAₘᵢₙ/2. A decrease value of the width of the ring structure 5 relative to the maximum width is selected as follows:

mCᵢ=Rᵢ−DIAₘᵢₙ/2−Cᵢ

which is used to replace an original width Cᵢ of the ring structure 5.

Correspondingly, the constraints are transformed into the first-level generalized coordinates representation:

denote,

RM=(DIAₘₐₓ−DIAₘᵢₙ)/2

as a maximum value of a radius difference between an outermost layer and an innermost layer.

Constraint i is transformed into:

$$RM - {\sum }_{i = 1}^{N - 1} {R}_{i\_i + 1} \geq 0$$

Constraint ii is transformed into:
mCᵢ≥0

Constraint iii is transformed into:
R_{i_i+1}−G≥0
D_{i_i+1}−G≥0
DLᵢ−(N−i)×G≥0

Constraint iv is transformed into:

$${\sum }_{i = 1}^{k} {R}_{i\_i + 1} - {mC}_{k + 1} - W \geq 0$$

wherein k=1, 2, . . . , N−1. If the innermost layer includes the ring structure 5, the value of k is as follows: k=0, 1, 2, . . . , N−1.

Constraint v is transformed into:
L_{A1P}≥0

Constraint vi is transformed into:
R_{i+1_i+2}−R_{i_i+1}≥0

For example, based on the example in step 205, the following first-level generalized coordinates are selected:

R₁₂=R₂−R₁

R₂₃=R₃−R₂

R₃₄=R₄−R₃

R₄₅=R₅−R₄

R₅₆=R₆−R₅

D₁₂=L_{A2}−L_{A1}

D₂₃=L_{A3}−L_{A2}

D₃₄=L_{A4}−L_{A3}

D₄₅=L_{A5}−L_{A4}

D₅₆=L_{A6}−L_{A5}

L_{A1P}=L_{A1}−h_{ROI}/2−F

DL₁=L_{B6}−L_{B1}

DL₂=L_{B6}−L_{B2}

DL₃=L_{B6}−L_{B3}

DL₄=L_{B6}−L_{B4}

DL₅=L_{B6}−L_{B5}

mC₂=R₂−R₁−C₂

mC₃=R₃−R₁−C₃

mC₄=R₄−R₁−C₄

mC₅=R₅−R₁−C₅

mC₆=R₆−R₁−C₆

The first-level generalized coordinates satisfy the following constraints:
268 mm−(R₁₂+R₂₃+R₃₄+R₄₅+R₅₆)≥0
mC₂, mC₃, mC₄, mC₅, mC₆≥0
R₁₂−10 mm≥0
R₂₃−10 mm≥0
R₃₄−10 mm≥0
R₄₅−10 mm≥0
R₅₆−10 mm≥0
D₁₂−10 mm≥0
D₂₃−10 mm≥0
D₃₄−10 mm≥0
D₄₅−10 mm≥0
D₅₆−10 mm≥0
DL₁−50 mm≥0
DL₂−40 mm≥0
DL₃−30 mm≥0
DL₄−20 mm≥0
DL₅−10 mm≥0
R₁₂−mC₂−10 mm≥0
R₁₂+R₂₃−mC₃−10 mm≥0
R₁₂+R₂₃+R₃₄−mC₄−10 mm≥0
R₁₂+R₂₃+R₃₄+R₄₅−mC₅−10 mm≥0
R₁₂+R₂₃+R₃₄+R₄₅+R₅₆−mC₆−10 mm≥0
L_{A1P}≥0
R₂₃−R₁₂≥0
R₃₄−R₂₃≥0
R₄₅−R₃₄≥0
R₅₆−R₄₅≥0

207: determining initial values of parameters to be optimized for subsequent calculation of the model.

There are two methods to determine the initial value of each parameter.

Method 1: selecting the initial values so that layers of the cylindrical magnetic shield are equally spaced. In the representation of the first-level generalized coordinates, values of R_{i_i+1} are the same for each i, values of D_{i_i+1} are the same for each i, a value of L_{A1P} is set to 0, a value of DLᵢ should satisfy that values of DLᵢ₊₁−DLᵢ are the same for each i, and values of mCᵢ are the same for each i. The foregoing values also need to satisfy the constraints in the step 205 or the transformed constraints in the step 206. If the step 206 is skipped, selection of the initial values still follows the foregoing principle.

For example, based on the example in step 206, the following initial values are selected: (the number in superscript parentheses is used to indicate a number of times of iterations in step 211, and the number 0 indicates that iteration has not yet been performed, indicating the initial value. The following is the same.)

R₁₂⁽⁰⁾=R₂₃⁽⁰⁾=R₃₄⁽⁰⁾=R₄₅⁽⁰⁾=R₅₆⁽⁰⁾=30 mm

D₁₂⁽⁰⁾=D₂₃⁽⁰⁾=D₃₄⁽⁰⁾=D₄₅⁽⁰⁾=D₅₆⁽⁰⁾=30 mm

L_{A1P}⁽⁰⁾=0

DL₁⁽⁰⁾=100 mm

DL₂⁽⁰⁾=80 mm

DL₃⁽⁰⁾=60 mm

DL₄⁽⁰⁾=40 mm

DL₅⁽⁰⁾=20 mm

mC₂⁽⁰⁾=mC₃⁽⁰⁾=mC₄⁽⁰⁾=mC₅⁽⁰⁾=mC₆⁽⁰⁾=0

The two-dimensional cross-sectional view drawn based on such an equal-spacing solution is shown in FIG. 11.

Method 2: The initial values are selected based on experience. The initial values need to be as close as possible to an optimized design, which can improve the calculation efficiency in step 211. The foregoing values also need to satisfy the constraints in the step 205 or the transformed constraints in the step 206.

For example, based on the example in the step 206, the following initial values are selected:

R₁₂⁽⁰⁾=20 mm

R₂₃⁽⁰⁾=30 mm

R₃₄⁽⁰⁾=40 mm

R₄₅⁽⁰⁾=50 mm

R₅₆⁽⁰⁾=110 mm

D₁₂⁽⁰⁾=D₂₃⁽⁰⁾=D₃₄⁽⁰⁾=D₄₅⁽⁰⁾=D₅₆⁽⁰⁾=30 mm

L_{A1P}⁽⁰⁾=0

DL₁⁽⁰⁾=870 mm

DL₂⁽⁰⁾=550 mm

DL₃⁽⁰⁾=410 mm

DL₄⁽⁰⁾=230 mm

DL₅⁽⁰⁾=80 mm

mC₂⁽⁰⁾=mC₃⁽⁰⁾=mC₄⁽⁰⁾=mC₅⁽⁰⁾=mC₆⁽⁰⁾=0

208: constructing the second-level generalized coordinates, and normalizing the parameters and constraints obtained from the first-level generalized coordinates.

Normalization brings the parameters to be optimized near a high-dimensional unit sphere in a parameter space, which is beneficial to improving the calculation efficiency of subsequent step 211. A specific method is to use the initial values to normalize first-level generalized coordinates whose initial value is not 0.

r_{i_i+1}=R_{i_i+1}/R_{i_i+1}⁽⁰⁾

d_{i_i+1}=D_{i_i+1}/D_{i_i+1}⁽⁰⁾

dlᵢ=DLᵢ/DLᵢ⁽⁰⁾

For the first-level generalized coordinates with an initial value of 0, a constant value is used for normalization. The constant value is generally 5G, and the value is related to assembly process and reflects the smallest details for assembly.

l_{A1P}=L_{A1P}/5G

mcᵢ=mCᵢ/5G

The value used for normalization is not limited to the foregoing selection. If design experience is available, the constants used for normalization can be adjusted.

Correspondingly, the constraints in the step 205 or the step 206 need to be transformed into the second-level generalized coordinates for description.

Constraint i is transformed into:

$$RM - {\sum }_{i = 1}^{N - 1} {r}_{i\_i + 1} \times {R}_{i\_i + 1}^{( 0 )} \geq 0$$

Constraint ii is transformed into:
mcᵢ≥0

Constraint iii is transformed into:
r_{i_i+1}−G/R_{i_i+1}⁽⁰⁾≥0
d_{i_i+1}−G/D_{i_i+1}⁽⁰⁾≥0
dlᵢ−(N−i)×G/DLᵢ⁽⁰⁾≥0

Constraint iv is transformed into:

$${\sum }_{i = 1}^{k} {r}_{i\_i + 1} \times {R}_{i\_i + 1}^{( 0 )} - m {c}_{k + 1} \times 5 G - W \geq 0$$

wherein k=1, 2, . . . , N−1. If the innermost layer includes the ring structure 5, the value of k is as follows: k=0, 1, 2, . . . , N−1.

Constraint v is transformed into:
l_{A1P}≥0

Constraint vi is transformed into:
r_{i+1_i+2}×R_{i_i+1}⁽⁰⁾−r_{i_i+1}×R_{i_i+1}⁽⁰⁾≥0

If the constant used for normalization is adjusted based on experience, the foregoing constraint conversion needs to be adjusted accordingly.

For example, based on Method 2 in the step 207, the second-level generalized coordinates are as follows:

r₁₂=R₁₂/R₁₂⁽⁰⁾

r₂₃=R₂₃/R₂₃⁽⁰⁾

r₃₄=R₃₄/R₃₄⁽⁰⁾

r₄₅=R₄₅/R₄₅⁽⁰⁾

r₅₆=R₅₆/R₅₆⁽⁰⁾

dl₁=DL₁/DL₁⁽⁰⁾

dl₂=DL₂/DL₂⁽⁰⁾

dl₃=DL₃/DL₃⁽⁰⁾

dl₄=DL₄/DL₃⁽⁰⁾

dl₅=DL₅/DL₅⁽⁰⁾

l_{A1P}=L_{A1P}/5G

mc₂=mC₂/5G

mc₃=mC₃/5G

mc₄=mC₄/5G

mc₅=mC₅/5G

mc₆=mC₆/5G

The constants used in the following normalization are adjusted by experience, that the normalization constant does not use D₁₂⁽⁰⁾=D₂₃⁽⁰⁾=D₃₄⁽⁰⁾=D₄₅⁽⁰⁾=D₅₆⁽⁰⁾=30 mm, but uses 5G instead. This is because D_{i_i+1} is expected to be slightly increased during optimization (It can be seen in the results of the example, that expectation is not satisfied).

d₁₂=D₁₂/5G

d₂₃=D₂₃/5G

d₃₄=D₃₄/5G

d₄₅=D₄₅/5G

d₅₆=D₅₆/5G

The following constraints are satisfied:
268 mm−(r₁₂×20 mm+r₂₃×30 mm+r₃₄×40 mm+r₄₅×50 mm+r₅₆×110 mm)≥0
mc₂, mc₃, mc₄, mc₅, mc₆≥0
r₁₂−0.5≥0
r₂₃−10/3≥0
r₃₄−0.25≥0
r₄₅−0.2≥0
r₅₆−1/11≥0
d₁₂−0.2≥0
d₂₃−0.2≥0
d₃₄−0.2≥0
d₄₅−0.2≥0
d₅₆−0.2≥0
dl₁−5/87≥0
dl₂−4/55≥0
dl₃−3/41≥0
dl₄−2/23≥0
dl₅−0.125≥0
r₁₂×20 mm−mc₂×50 mm−10 mm≥0
r₁₂×20 mm+r₂₃×30 mm−mc₃×50 mm−10 mm≥0
r₁₂×20 mm+r₂₃×30 mm+r₃₄×40 mm−mc₄×50 mm−10 mm≥0
r₁₂×20 mm+r₂₃×30 mm+r₃₄×40 mm+r₄₅×50 mm−mc₅×50 mm−10 mm≥0
r₁₂×20 mm+r₂₃×30 mm+r₃₄×40 mm+r₄₅×50 mm+r₅₆×110 mm−mc₆×50 mm−10 mm≥0
l_{A1P}≥0
r₂₃×30 mm−r₁₂×20 mm≥0
r₃₄×40 mm−r₂₃×30 mm≥0
r₄₅×50 mm−r₃₄×40 mm≥0
r₅₆×110 mm−r₄₅×50 mm≥0

Initial values are as follows:

r₁₂⁽⁰⁾=1

r₂₃⁽⁰⁾=1

r₃₄⁽⁰⁾=1

r₄₅⁽⁰⁾=1

r₅₆⁽⁰⁾=1

dl₁⁽⁰⁾=1

dl₂⁽⁰⁾=1

dl₃⁽⁰⁾=1

dl₄⁽⁰⁾=1

dl₅⁽⁰⁾=1

l_{A1P}⁽⁰⁾=0

mc₂⁽⁰⁾=0

mc₃⁽⁰⁾=0

mc₄⁽⁰⁾=0

mc₅⁽⁰⁾=0

mc₆⁽⁰⁾=0

d₁₂⁽⁰⁾=0.6

d₂₃⁽⁰⁾=0.6

d₃₄⁽⁰⁾=0.6

d₄₅⁽⁰⁾=0.6

d₅₆⁽⁰⁾=0.6

209: constructing the derivative-free optimization model.

i. Constructing an objective function: determining a function Φ as an optimization target, and using the optimization algorithm to find a combination of independent variables that minimizes the function.

In an embodiment, there are two methods to construct the objective function:

Method 1: Φ is defined as an integral of magnetic flux density norm to volume in the region of interest 2, and a typical value B₀ of magnetic flux density norm and a total volume V₀ are used for normalization:

$$Φ = \frac{1}{{V}_{0} {B}_{0}} {\int }_{R} {\int }_{O} {\int }_{I} \vert B \vert dV$$

wherein B₀ is set to a value of a residual magnetic flux density norm of the region of interest 2 when the shielding performance is close to expectation.

Method 2: A surface, closest to the open end 3, of the region of interest 2 is selected, the objective function Φ is defined as an integral of magnetic flux density norm on this surface to area, and a typical value B₀ of magnetic flux density norm and a total area S₀ are used for normalization:

$$Φ = \frac{1}{{S}_{0} {B}_{0}} {\int \int }_{ROI\_S} \vert B \vert dS$$

The value of the objective function is obtained through calculation in step 210.

In this example, the second method is used. The region of interest 2 (ROI) is the cylinder in step 201, the area of the surface close to the open end 3 is S₀=πR_{ROI}², and the typical value is B₀=0.2 nT.

ii. Constructing a parameter set to be optimized: determining independent variables of the objective function, and using the optimization algorithm to find a minimum value of the objective function in a space spanned by the parameters to be optimized.

In an embodiment, the parameter set to be optimized is the second-level generalized coordinates constructed in the step 208.

Alternatively, the first-level generalized coordinates constructed in the step 206 or the complete parameter set determined in the step 204 can be selected.

In this example, the parameter set to be optimized is the second-level generalized coordinates constructed in step 208, and the parameter set to be optimized includes the following parameters:

r₁₂, r₂₃, r₃₄, r₄₅, r₅₆, dl₁, dl₂, dl₃, dl₄, dl₅, l_{A1P}, mc₂, mc₃, mc₄, mc₅, mc₆,

d₁₂, d₂₃, d₃₄, d₄₅, d₅₆.

iii. Determining bounds of the parameters to be optimized: determining upper bounds and lower bounds of the parameters to be optimized, so as to determine a search range of parameters. The determined range needs to be a subset of the parameter range defined by the constraints in the step 205. There are two types of bounds in the present application. The first type of bounds is determined by the constraints, which includes upper bounds and lower bounds. The second type of bound is determined by the constants in the derivative-free optimization model, which includes only upper bounds. If a bound of the second type is reached during calculation, it indicates that the selected constant of the derivative-free optimization model is too small; if a bound of the first type is reached, it is a normal phenomenon. The second type of bounds is used to define non-monotonically increasing independent variables.

Denote,

RU=(DIAₘₐₓ−DIAₘᵢₙ)/2−(N−2)×G

as a maximum value of a radius difference between two adjacent layers. In this case,
G≤R_{i_i+1}≤RU

or
G/R_{i_i+1}⁽⁰⁾≤r_{i_i+1}≤RU/R_{i_i+1}⁽⁰⁾

D_{i_i+1} is a non-monotonically increasing independent variable, its lower bound is defined by G, and its upper bound is selected as a constant D_{i_i+1_max} based on an actual geometry. As long as the constant is large enough, the value of the constant does not influence a final result, but only affect the search efficiency. Sufficiently large means that none of the parameters reach the upper bounds defined by the constants in a final optimization result. If there is a parameter that reaches an upper bound, it indicates that the corresponding constant is not large enough. The method of the present application needs to be performed again starting from this step after the constant is increased. D_{i_i+1_max} belongs to the second type of bounds.

The upper and lower bounds of D_{i_i+1} are as follows:
G/D_{i_i+1}⁽⁰⁾≤d_{i_i+1}≤D_{i_i+1_max}/D_{i_i+1}⁽⁰⁾

or
G≤d_{i_i+1}≤D_{i_i+1_max}

DLᵢ is a non-monotonically increasing independent variable, its lower bound is defined by (N−i)×G, and its upper bound is selected as a constant DL_{i_max} based on an actual geometry. As long as the constant is large enough, the value of the constant does not influence a final result, but only affect the search efficiency. Sufficiently large means that none of the parameters reach the upper bounds defined by the constants in a final optimization result. If there is a parameter that reaches an upper bound, it indicates that the constant is not large enough. The method of the present application needs to be performed again starting from this step after the constants are increased. The upper and lower bounds of DLᵢ are as follows:
(N−i)×G≤DLᵢ≤DL_{i_max}

or
(N−i)×G/DLᵢ⁽⁰⁾≤dlᵢ≤DL_{i_max}/DLᵢ⁽⁰⁾

L_{A1P} is a the non-monotonically increasing independent variable, its lower bound is 0, and its upper bound is selected as a constant L_{A1P_max} based on actual geometry. As long as the constant is large enough, the value of the constant does not influence a final result, and only influence search efficiency. Sufficiently large means that none of the parameters reach the upper bounds defined by the constants in a final optimization result. If there is a parameter that reaches an upper bound, it indicates that the constant is not large enough. The method of the present application needs to be performed again starting from this step after the constants are increased. The upper and lower bounds of L_{A1P} are as follows:
0≤L_{A1P}≤L_{A1P_max}

or
0≤l_{A1P}≤L_{A1P_max}/5G

The upper and lower bounds of mCᵢ are as follows:
W≤mCᵢ≤RM

or
W/5G≤mcᵢ≤RM/5G

If the constants used for normalization are adjusted based on experience in step 208, the foregoing constraint conversion needs to be adjusted accordingly.

In this example, bounds of the parameters to be optimized are as follows:
0.5≤r₁₂≤11.4
1/3≤r₂₃≤7.6
0.25≤r₃₄≤5.7
0.2≤r₄₅≤4.56
1/11≤r₅₆≤114/55
5/87≤dl₁≤160/87
4/55≤dl₂≤32/11
3/41≤dl₃≤160/41
2/34≤dl₄≤160/23
0.125≤dl₅≤20
0≤l_{A1P}≤4
0.2≤mc₂≤5.36
0.2≤mc₃≤5.36
0.2≤mc₄≤5.36
0.2≤mc₅≤5.36
0.2≤mc₆≤5.36
0.2≤d₁₂≤6
0.2≤d₂₃≤6
0.2≤d₃₄≤6
0.2≤d₄₅≤6
0.2≤d₅₆≤6

Herein the following values are selected.

D_{i_i+1_max}=300 mm

DL_{i_max}=1600 mm

L_{A1P_max}=200 mm

iv. Selecting a search method. Various derivative-free optimization algorithms can be selected.

In an embodiment, when N≤2, an exhaustive search method is selected; when 2<N≤4, a Nelder-Mead method is selected; when N>4, a coordinate search method is selected.

A penalty function is constructed using the constraints in the step 205 or 206 or 208 and added to the objective function.

Various methods can be implemented by using commercial software such as Ansys Maxwell, COMSOL Multiphysics, and a MATLAB-based software package, and open source or semi-open source software such as deal.II, and Elmer.

In this example, the coordinate search method is selected.

For the model obtained in step 209, its output is the value of the parameter to be optimized, and its input is the value of the objective function.

210: constructing a finite element model.

i. Using parameters in the step 204 to construct geometry. The generalized coordinates defined in the step 206 or 208 need to be converted back into the parameters in the complete parameter set according to their definitions, to be used to construct the geometry.

In this example, the generalized coordinates defined in step 208 are converted back into the parameters in the complete parameter set, to be used to construct the geometry.

ii. Equations to be solved are as follows.

In an embodiment, the following wave equation of magnetic vector potential on the symmetrical section 6 is to be solved:

∇×(∇×A)=0

which is simplified as:

$$\{ \begin{matrix}\frac{{\partial }^{2} ( r {A}_{ϕ} )}{\partial ϕ \partial r} = 0 \\ \frac{{\partial }^{2} {A}_{ϕ}}{\partial {z}^{2}} + \frac{\partial }{\partial r} [ \frac{1}{r} \frac{\partial ( r {A}_{ϕ} )}{\partial r} ] = 0 \\ \frac{{\partial }^{2} {A}_{ϕ}}{\partial ϕ \partial z} = 0\end{matrix}$$

wherein A_{ϕ} denotes a component, perpendicular to the symmetrical section 6, of the magnetic vector potential, which is along the ϕ axis of the cylindrical coordinate system in the three-dimensional space in FIG. 10.

A boundary condition is as follows:

n×A=0

wherein n denotes a unit normal vector at boundaries of a domain to be solved.

magnetic flux density is finally given by the following formula:

B=∇×A

In another embodiment, the following wave equation of a magnetic scalar potential is to be solved as an alternative:

ΔVₘ=0

A boundary condition is as follows:

n·∇Vₘ=0

wherein n denotes a unit normal vector at boundaries of a domain to be solved.

magnetic flux density is finally given by the following formula:

B=−μ∇Vₘ

wherein μ denotes magnetic permeability.

In this example, the wave equation of the magnetic vector potential is solved.

iii. Thin layers of the cylindrical magnetic shield are treated.

In an embodiment, each layer of the cylindrical magnetic shield is treated as a boundary condition without geometric thickness, and a thickness and magnetic property of the material in step 202 both contribute to the boundary condition.

The contribution of the magnetic property to the boundary condition is given by constitutive relations as follows:

B=B(H)

or

H=H(B)

When the equations of the magnetic vector potential are solved, boundary conditions are as follows:

$$n \times ( {H}_{1} - {H}_{2} ) = n \times {H}_{t} {H}_{t} = {H}_{t} ( {B}_{t} ) {B}_{t} = n \times ( \frac{{A}_{1} - {A}_{2}}{d} )$$

wherein H₁, H₂ denote magnetic flux strength on both sides of a boundary, Hₜ denotes a shared portion of the thin layer for tangential magnetic field strength, Bₜ denotes a shared portion of the thin layer for tangential magnetic flux density, and d denotes the layer thickness, which is given in the step 202.

When the equations of a magnetic scalar potential are solved, boundary conditions are as follows:

n·(B₁−B₂)=−∇·(dBₜ)

Bₜ=Bₜ(Hₜ)

Hₜ=∇ₜVₘ

wherein B₁, B₂ denote magnetic flux density on both sides of a boundary, and ∇ₜ denotes a gradient calculated in a tangential direction of the boundary.

In another embodiment, each layer of the cylindrical magnetic shield may alternatively be treated as a geometric entity with a certain thickness. When a layer thickness is much less than an overall size of the cylindrical magnetic shield, only the first method can be used; otherwise, the second method can be used.

In this example, each layer of the cylindrical magnetic shield is treated as a boundary condition without geometric thickness.

iv. A background magnetic flux density is applied.

A uniform background magnetic flux density B₀ in the axial direction is applied. In this case, magnetic flux density norm in the region of interest 2 is calculated, which can reflect axial shielding performance of the system. Researches have shown that axial shielding performance of a cylindrical magnetic shield with a single end open is the lowest. Therefore, it is more reasonable to take the axial shielding performance as an optimization target.

When the equations of the magnetic vector potential are solved, the background magnetic flux density is converted into magnetic vector potential and then added to the equations to be solved and the boundary conditions. When the equations of the magnetic scalar potential are solved, the background magnetic flux density is converted into background magnetic field strength and then added to the equations to be solved and the boundary conditions.

When the magnetic property of the material obtained in the step 202 is represented by a magnetic permeability, the background magnetic flux density may be set to any value. When the magnetic property is represented by the initial B-H or H-B curve, the background magnetic flux density should be less than a maximum magnetic field strength of an initial magnetization region after being converted into the magnetic field strength.

In this example, B₀=1000 nT is selected.

v. Discretization and Solving are Performed.

In another embodiment, Lagrange quadratic elements are used for discretization. Alternatively, linear elements or higher-order elements can be used for discretization. A mesh generation method and a solver are implemented by using methods provided in commercial software such as Ansys Maxwell, COMSOL Multiphysics, MATLAB-based software packages, and open source or semi-open source software such as deal.II, and Elmer.

In this example, the Lagrange quadratic elements are used for discretization, and COMSOL Multiphysics is used for the mesh generation and solving.

vi. An objective function is calculated.

If Method 1 is used in step 209, it is assumed that the region of interest 2 includes K elements, an average value of magnetic flux density norm of each node calculated on the j^{th} element is Bⱼ, and area of the node is ΔSⱼ. In this case, the objective function is given as follows:

$$Φ = \frac{1}{{V}_{0} {B}_{0}} {\sum }_{j = 1}^{K} {B}_{j} Δ {S}_{j} \times 2 π {r}_{j}$$

wherein rⱼ denotes a distance from the element to the axis of symmetry.

If the Method 2 is used in the step 209, it is assumed that a surface, closest to the open end 3, of the region of interest 2 includes K elements, an average value of magnetic flux density norm of each node calculated on the j^{th} element is Bⱼ, and length of the node is Δlⱼ. In this case, the objective function is given as follows:

$$Φ = \frac{1}{{S}_{0} {B}_{0}} {\sum }_{j = 1}^{K} {B}_{j} Δ {l}_{j} \times 2 π {r}_{j}$$

wherein rⱼ denotes a distance from the element to the axis of symmetry.

Other calculation methods provided in the used software can alternatively be used.

In this example, a calculation method provided in COMSOL Multiphysics is used.

The input of the model obtained in the step 210 is the values of the parameters to be optimized, and the output is the value of the objective function.

211: performing repeated calculation or iterative calculation to obtain optimal parameters.

The initial values obtained in the step 207 or the initial values obtained after the processing in the step 208 are input into the model in the step 210, to obtain the objective function value through calculation, and a result is input into the model in the step 209, to obtain new values of parameters to be optimized through calculation. The new values of parameters to be optimized are input into the model in the step 210. This process is repeated calculation when the derivative-free optimization algorithm selected in the step 209 determines, independent of the input objective function value, values of parameters to be optimized selected for a next calculation (for example, the exhaustive search method). This process is iterative calculation when the derivative-free optimization algorithm selected in the step 209 determines, depending on the input objective function value, the values of the parameters to be optimized selected for the next calculation (for example, the Nelder-Mead method). In the case of repeated calculation, after all calculations are completed, a parameter value combination with the smallest objective function is selected as the output. In the case of iterative calculation, a condition for terminating the iteration needs to be set in advance. After M iterations, output of parameters to be optimized are as follows:
r_{i_i+1}^{(M)}, d_{i_+1}^{(M)}, dlᵢ^{(M)}, l_{A1P}^{(M)}, mcᵢ^{(M)}

In this example, the condition for terminating the iteration is that the optimization tolerance τ=0.001, and an actual quantity of iterations reaches 572. Optimized parameter values of the output parameters to be optimized are as follows:

r₁₂⁽⁵⁷²⁾=0.985

r₂₃⁽⁵⁷²⁾=1.439

r₃₄⁽⁵⁷²⁾=1.126

r₄₅⁽⁵⁷²⁾=1.000

r₅₆⁽⁵⁷²⁾=1.000

dl₁⁽⁵⁷²⁾=1.038

dl₂⁽⁵⁷²⁾=1.090

dl₃⁽⁵⁷²⁾=0.999

dl₄⁽⁵⁷²⁾=1.058

dl₅⁽⁵⁷²⁾=1.192

l_{A1P}⁽⁵⁷²⁾=0

mc₂⁽⁵⁷²⁾=0

mc₃⁽⁵⁷²⁾=0

mc₄⁽⁵⁷²⁾=0

mc₅⁽⁵⁷²⁾)=0

mc₆⁽⁵⁷²⁾=0

d₁₂⁽⁵⁷²⁾=0.204

d₂₃⁽⁵⁷²⁾=0.271

d₃₄⁽⁵⁷²⁾=0.224

d₄₅⁽⁵⁷²⁾=0.204

d₅₆⁽⁵⁷²⁾=0.227

212: performing assessment and outputting a result.

i. Determining whether the output parameters reach the bounds of the second type specified in the step 209. iii. If yes, it indicates that the constants are too small, and larger constants should be selected to perform the method again starting from step 209. If no, setting of the constants is adequate.

ii. Determining, in the last iteration or the calculation of a set of parameters with the smallest objective function values in repeated calculation, whether the objective function output from the finite element model in the step 210 into the derivative-free optimization model meets the preset threshold. If no, a reason is analyzed, and the input of the derivative-free optimization model is modified based on the analysis result. Specifically, consider replacing the material, modifying the quantity of layers, loosing the constraints, and adopting more stringent iteration termination criteria or more repeated calculations, and the method should be performed again starting from the corresponding step. If yes, a result is output by the derivative-free optimization model. If the generalized coordinates are used, the generalized coordinates need to be converted back into the parameters in the complete parameter set and are then output.

In this example, none of the output parameters reaches the upper bounds of the non-monotonically increasing independent variables defined by the constants specified in step the 209. iii. After the last iteration, the objective function value satisfies the expectation. The parameters to be optimized are converted back from the second-level generalized coordinates into the parameters in the complete parameter set, to obtain result parameters as follows:

R₁=361.0 mm

R₂=380.7 mm

R₃=423.9 mm

R₄=468.9 mm

R₅=518.9 mm

R₆=628.9 mm

L_{A1}=350.0 mm

L_{A2}=360.2 mm

L_{A3}=373.7 mm

L_{A4}=385.0 mm

L_{A5}=395.2 mm

L_{A6}=406.5 mm

L_{B1}=869.1 mm

L_{B2}=1173.1 mm

L_{B3}=1362.9 mm

L_{B4}=1529.2 mm

L_{B5}=1677.1 mm

L_{B6}=1772.5 mm

C₂=19.7 mm

C₃=62.9 mm

C₄=107.9 mm

C₅=157.9 mm

C₆=267.9 mm

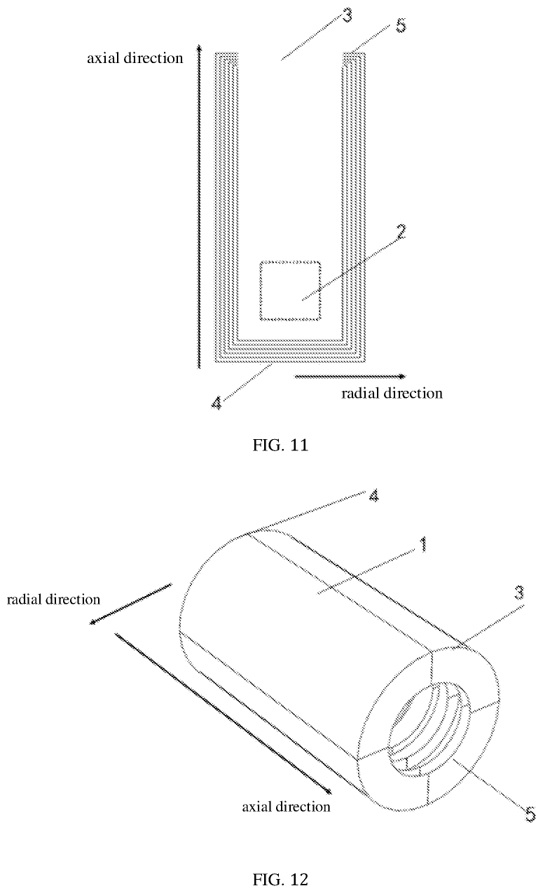

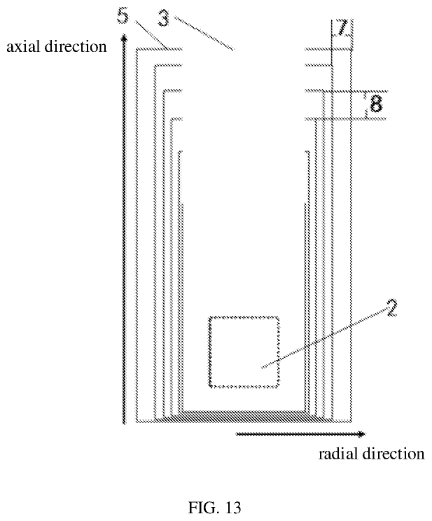

A three-dimensional view of the optimized cylindrical magnetic shield obtained according to this example is shown in FIG. 12, and a two-dimensional cross-sectional view is shown in FIG. 13.

An exemplary embodiment of the present application proposes a complete set of optimization design methods for magnetic shielding apparatuses with an opening. Not only are the optimization methods more scientific, the optimization efficiency is higher, but also the magnetic shielding performance of the optimized cylindrical magnetic shield is greatly improved compared with that of the cylindrical magnetic shield using the equal-spacing solution. Specifically, a typical shielding factor is increased by more than 5 times. For example, for the 6-layer cylindrical magnetic shield in some examples, based on the average value in the region of interest 2, the shielding factor of the cylindrical magnetic shield using the equal-spacing solution is 1722, while the shielding factor of the optimized cylindrical magnetic shield is 12720, and fewer raw materials are used. In addition, an axial shielding factor under a quasistatic magnetic field is taken as the optimization target, aiming at the direction wherein the shielding performance of the system is the lowest, thereby achieving a significant optimization effect. The foregoing shielding coefficient is calculated based on a ratio of the background magnetic flux density norm to the magnetic flux density norm in the region of interest. The foregoing comparison result is obtained based on the following method: Before the magnetic shielding apparatus is optimized and after the region of interest inside the magnetic shielding apparatus is selected, the magnetic shielding factor in the region of interest is calculated; and after the magnetic shielding apparatus is optimized, the magnetic shielding factor in the region of interest is re-calculated based on the same background magnetic flux density norm.

Exemplary Computer-Readable Storage Medium

An exemplary embodiment of the present application provides a computer-readable storage medium. The storage medium stores a computer program, and the computer program is used to perform the method for designing a magnetic shielding apparatus in the foregoing exemplary methods.

Exemplary Electronic Device

An exemplary embodiment of the present application provides an electronic device, including a processor and a memory configured to store an instruction executable by the processor, wherein the processor is configured to perform the method for designing a magnetic shielding apparatus in the foregoing exemplary methods.

Exemplary Software Product

An exemplary embodiment of the present application provides a software product, and the software product runs the method for designing a magnetic shielding apparatus in the exemplary methods.

Exemplary Magnetic Shielding Apparatus

This embodiment provides a magnetic shielding apparatus, including: N layers of shields 1 nested together, wherein N>1, and the magnetic shielding apparatus is designed based on the method for designing a magnetic shielding apparatus in the exemplary methods.

In an embodiment, there is a length difference 8 between adjacent shields 1 of the N layers of shields 1 at at least one of two ends in a working direction of the magnetic shielding apparatus, and/or there is an assembly gap 7 between adjacent shields 1 in the N layers of shields 1 in a direction perpendicular to a working direction of the magnetic shielding apparatus, and optimized parameters in a complete parameter set of the magnetic shielding apparatus include the assembly gap 7 and/or the length difference 8. Specifically, a plurality of solutions included in this embodiment are as follows: Solution 1: There is the length difference 8 between adjacent shields 1 of the N layers of shields 1 at either end of two ends in a working direction of the magnetic shielding apparatus. This solution is relatively suitable for a magnetic shielding apparatus with a single end open, and the length difference 8 is located at the open side. Solution 2: There is the length difference 8 between adjacent shields 1 of the N layers of shields 1 at two ends in a working direction of the magnetic shielding apparatus, which is relatively suitable for a solution in which two ends are open, or a solution in which two ends are closed. Solution 3: There is the length difference 8 between adjacent shields 1 of the N layers of shields 1 at either end of two ends in a working direction of the magnetic shielding apparatus, and there is an assembly gap 7 between adjacent shields 1 in the N layers of shields 1 in a direction perpendicular to a working direction of the magnetic shielding apparatus. Solution 4: There is the length difference 8 between adjacent shields 1 of the N layers of shields 1 at two ends in a working direction of the magnetic shielding apparatus, and there is an assembly gap 7 between adjacent shields 1 in the N layers of shields 1 in a direction perpendicular to a working direction of the magnetic shielding apparatus. Both the length difference 8 and the assembly gaps 7 in each solution are different from those determined by experience in the prior art, and the length difference 8 and the assembly gaps 7 in the present application are all obtained finally through optimization according to the method for designing a magnetic shielding apparatus. In addition, in the direction perpendicular to the working direction of the magnetic shielding apparatus, at least one assembly gap 7 is greater than 5% of a dimension, in the direction perpendicular to the working direction, of an inner one of two adjacent layers of shields that produces the assembly gap 7. In the working direction of the magnetic shielding apparatus, at least the length difference 8 is greater than 10% of a total length, in the working direction, of a shorter one of two adjacent layers of shields that produces the length difference 8. For the cylindrical magnetic shield with a single end open and having 6 layers of shields provided in the foregoing exemplary methods, in its working direction, the length difference 8 between an innermost layer and a secondary inner layer reaches 24.9% of a total length of the innermost layer; in a direction perpendicular to the working direction, an assembly gap 7 between a secondary outer layer and an outermost layer (namely, a radius difference for this apparatus) reaches 10.5% of the diameter of the secondary outer layer.

Regarding a specific feature of the optimized length difference 8 and the assembly gap 7, in an embodiment, at least three layers of shields 1 are provided for the N layers of shields, and at least two assembly gaps 7 between every two adjacent shields 1 are not equal and/or at least two of the length difference 8 between every two adjacent shields 8 are not equal.

In an embodiment, basic geometric structures of the N layers of shields 1 of the magnetic shielding apparatus are the same and all have symmetry; an opening is provided at one end of the N layers of shields 1 in an axial direction of an axis of symmetry of the N layers of shields 1, to form an open end 3 of the magnetic shielding apparatus, and the other end disposed opposite to the open end 3 is a closed end 4 of the magnetic shielding apparatus; and the length differences 8 of the N layers of shields 1 are formed near the open end 3 of the magnetic shielding apparatus.

In order to improve a magnetic shielding effect of the magnetic shielding apparatus, in an embodiment, a shielding structure extending in a direction from an outer edge of the shield 1 to the axis of symmetry of the N layers of shields is provided at an open end 3 of at least one layer of shield 1 in the N layers of shields 1, and the assembly gaps 7 are formed between shielding structures of different layers in a direction perpendicular to the axis of symmetry of the N layers of shields 1. In an embodiment, an outer edge of an innermost layer of shield in the N layers of shields is stretched in a direction perpendicular to a plane wherein the opening is located to form a curved surface, and the shielding structure extends to the curved surface. In an embodiment, the shielding structure is provided at an opening of each of N−1 layers of shields 1, in the N layers of shields 1, except an innermost layer of shield. The magnetic shielding effect of the magnetic shielding apparatus is improved, and an internal use space of the magnetic shielding apparatus is not affected. In an embodiment, the basic geometric structures of the N layers of shields 1 are cylindrical structures with cylindrical symmetry, and the shielding structure is a ring structure 5. That is, the basic geometric structure of the magnetic shielding apparatus is in a cylindrical shape with a single end open and a plurality of layers nested.

Generally, the higher the symmetry of the basic geometric structure of the magnetic shielding apparatus, the better the magnetic shielding effect, and the greater the processing difficulty. The cylindrical magnetic shielding apparatus has cylindrical symmetry and is easy to process, which can achieve a good magnetic shielding effect at a low cost and be processed into a small magnetic shielding apparatus, or a medium-large magnetic shielding apparatus. Many studies show that increasing thickness of a single-layer shielding shield 1 has no obvious effect on increase of shielding performance. However, when a thin shield is used to make a multi-layer shielding apparatus, as a quantity of layers increases, the shielding performance increases significantly. Therefore, the magnetic shielding apparatus used in this embodiment is a cylindrical magnetic shield with a single end open and a plurality of layers nested. In addition, the magnetic shielding performance of the optimized magnetic shielding apparatus shown in FIG. 13 is greatly improved compared with that of the magnetic shielding apparatus shown in FIG. 11 using a solution of equal spacing between shields, and a typical shielding factor is increased by more than 5 times.

Exemplary Apparatus

This embodiment provides an apparatus for designing a magnetic shielding apparatus, including: a first determining module, a second determining module and a parameter optimization module. The first determining module is configured to determine a region of interest inside the magnetic shielding apparatus, wherein the region of interest is a region where a magnetic shielding effect is expected to be achieved, and the magnetic shielding apparatus includes N layers of shields disposed in a nested manner. The second determining module is configured to determine a complete parameter set, wherein the complete parameter set is used to describe a geometric structure of at least one layer of shield in the N layers of shields and a relative positional relationship between the region of interest and each layer of shield in the at least one layer of shield. The parameter optimization module is configured to obtain, based on the complete parameter set, a set of result parameters for describing the geometric structure, wherein the result parameters enable magnetic flux density in the region of interest to meet a preset threshold.

In conclusion, the present application provides a method and an apparatus for designing a magnetic shielding apparatus and a magnetic shielding apparatus. The method includes: determining a region of interest inside the magnetic shielding apparatus, wherein the region of interest is a region where a magnetic shielding effect is expected to be achieved, and the magnetic shielding apparatus includes N layers of shields disposed in a nested manner; determining a complete parameter set, wherein the complete parameter set is used to describe a geometric structure of at least one layer of shield in the N layers of shields and a relative positional relationship between the region of interest and each layer of shield in the at least one layer of shield; and obtaining, based on the complete parameter set, a set of result parameters for describing the geometric structure, wherein the result parameters enable magnetic flux density in the region of interest to meet a preset threshold. This method is more scientific and efficient, which not only greatly improves optimized magnetic shielding performance compared with an equal-spacing solution, but also resolves a problem that an analytical method cannot be used to optimize design of a non-concentric structure magnetic shielding apparatus with a single end open.

All of the foregoing optional technical solutions may be randomly combined to form optional embodiments of the present application. Details are not described herein.

In the description of this specification, the description with reference to the terms “an embodiment”, “some embodiments”, “an example”, or the like means that specific features, structures, materials or characteristics described in combination with the embodiments or examples are included in at least one embodiment or example of the present application. In this specification, the schematic representation of the foregoing terms does not necessarily refer to the same embodiment or example. Moreover, the described specific features, structures, materials, or characteristics may be combined in any one or more embodiments or examples in an appropriate manner.

Unless otherwise defined, all technical and scientific terms used in this specification have the same meaning as commonly understood by those skilled in the technical field of the present application. The terms used in the specification of the present application are merely for the purpose of describing specific embodiments, and are not intended to limit the present application. The term “and/or” used in this specification includes any and all combinations of one or more related listed items.

Those skilled in the art may be aware that, in combination with the examples described in the embodiments disclosed in this specification, units and algorithm steps can be implemented by electronic hardware or a combination of computer software and electronic hardware. Whether the functions are performed by hardware or software depends on particular applications and design constraints of the technical solutions. A person skilled in the art may use different methods to implement the described functions for each particular application, but it should not be considered that the implementation goes beyond the scope of the present application.

It may be clearly understood by a person skilled in the art that, for the purpose of convenient and brief description, for a detailed working process of the foregoing system, apparatus, and unit, reference may be made to a corresponding process in the foregoing method embodiments, and details are not described herein again.

In the several embodiments provided in the present application, it should be understood that the disclosed system, apparatus, and method may be implemented in other manners. For example, the described apparatus embodiment is merely an example. For example, the unit division is merely logical function division and may be other division in actual implementation. For example, a plurality of units or components may be combined or integrated into another system, or some features may be ignored or not performed. In addition, the displayed or discussed mutual couplings or direct couplings or communication connections may be implemented by using some interfaces. The indirect couplings or communication connections among the apparatuses or units may be implemented in electronic, mechanical, or other forms.

The units described as separate parts may or may not be physically separate, and parts displayed as units may or may not be physical units, may be located at one position, or may be distributed on a plurality of network units. Some or all of the units may be selected based on actual requirements to achieve the objectives of the solutions of the embodiments.

In addition, functional units in the embodiments of the present application may be integrated into one processing unit, or each of the units may exist alone physically, or two or more units may be integrated into one unit.

When the functions are implemented in the form of a software functional unit and sold or used as an independent product, the functions may be stored in a computer-readable storage medium. Based on such an understanding, the technical solutions of the present application essentially, or the part contributing to the prior art, or some of the technical solutions may be implemented in a form of a software product. The software product is stored in a storage medium, and includes several instructions for instructing a computer device (which may be a personal computer, a server, a network device, or the like) to perform all or some of the steps of the methods described in the embodiments of the present application. The foregoing storage medium includes: any medium that can store program codes, such as a USB flash drive, a removable hard disk, a read-only memory (ROM, Read-Only Memory), a random-access memory (RAM, Random Access Memory), a magnetic disk, or an optical disc.

It should be noted that, in the description of the present application, the terms “first”, “second”, “third”, and the like are merely used for a purpose of description, and shall not be understood as an indication or implication of relative importance. In addition, in the descriptions of the present application, unless otherwise stated, “a plurality of” means at least two.

The foregoing descriptions are merely preferable embodiments of the present application, but are not intended to limit the present application. Any modification, equivalent replacement, and the like made without departing from the spirit and principle of the present application shall fall within the protection scope of the present application.

What is claimed is:

1. A method for designing a magnetic shielding apparatus, comprising:
determining a region of interest inside the magnetic shielding apparatus, the region of interest being a region where a magnetic shielding effect is expected, and the magnetic shielding apparatus comprising N layers of shields disposed in a nested manner;
determining a complete parameter set, the complete parameter set being configured to describe a geometric structure of at least one layer of shield in the N layers of shields and a relative positional relationship between the region of interest and each layer of shield in the at least one layer of shield; and
obtaining, based on the complete parameter set, a set of result parameters for describing the geometric structure, wherein the set of result parameters enable magnetic flux density in the region of interest to meet a preset threshold.

2. The method according to claim 1, wherein the obtaining, based on the complete parameter set, a set of result parameters for describing the geometric structure comprises:
inputting the complete parameter set as independent variables and the magnetic flux density in the region of interest as a dependent variable into a derivative-free optimization model to obtain a set of optimal parameters though calculation of the derivative-free optimization model, wherein the independent variables comprise non-monotonically increasing independent variables, and the dependent variable does not increase monotonically when the non-monotonically increasing independent variables increase, and constants are set to define upper bounds of the non-monotonically increasing independent variables in the derivative-free optimization model; and
verifying whether the non-monotonically increasing independent variables in the optimal parameters reach the upper bounds defined by the constants,
if yes, increasing the constants in the derivative-free optimization model and then re-executing the step of inputting the complete parameter set as independent variables and the magnetic flux density in the region of interest as a dependent variable into a derivative-free optimization model;
if no, verifying whether the magnetic flux density in the region of interest of the magnetic shielding apparatus with the optimal parameters meets the preset threshold; and if yes, outputting results, and the results output are the set of result parameters; if no, adjusting an input of the derivative-free optimization model, and then re-executing calculation of the derivative-free optimization model.

3. The method according to claim 2, wherein the inputting the complete parameter set as independent variables and the magnetic flux density in the region of interest as a dependent variable into a derivative-free optimization model to obtain a set of optimal parameters comprises: obtaining optimization parameters based on the complete parameter set through calculation of the derivative-free optimization model, converting the optimization parameters into the magnetic flux density by using a method for obtaining magnetic field distribution of the magnetic shielding apparatus from the geometric structure, and obtaining the optimal parameters and the magnetic flux density in the region of interest of the magnetic shielding apparatus with the optimal parameters by using repeated calculation or iterative calculation during calculation of the derivative-free optimization model.

4. The method according to claim 3, wherein the method for obtaining magnetic field distribution of the magnetic shielding apparatus from the geometric structure comprises a finite element method.

5. The method according to claim 1, wherein basic geometric structures of the N layers of shields are the same and all have symmetry, and the region of interest is a three-dimensional space.

6. The method according to claim 5, wherein a center of the region of interest is on a symmetry plane of the N layers of shields.

7. The method according to claim 5, wherein the region of interest has axial symmetry, and an axis of symmetry of the region of interest coincides with an axis of symmetry of the N layers of shields.

8. The method according to claim 1, wherein the determining the complete parameter set comprises:
determining basic parameters of the magnetic shielding apparatus based on the preset threshold of the magnetic flux density of the region of interest; and
determining the complete parameter set based on the basic parameters, wherein the basic parameters comprise parameters used to represent a basic geometric structure of the magnetic shielding apparatus, a quantity of layers of shields comprised by the magnetic shielding apparatus, materials of the N layers of shields, a thickness of each layer of shields, a size of the region of interest, and a position of the region of interest relative to the magnetic shielding apparatus.

9. The method according to claim 1, wherein the obtaining, based on the complete parameter set, a set of result parameters for describing the geometric structure comprises:
determining constraints; and
obtaining, based on the constraints and the complete parameter set, the set of result parameters for describing the geometric structure, wherein the constraints limit a range of parameters in the complete parameter set.

10. The method according to claim 1, further comprising:
selecting, based on the complete parameter set, independent parameters having the same quantity of parameters as the complete parameter set, wherein the independent parameters have the same completeness as the complete parameter set to completely describe the geometric structure;
constructing first-level generalized coordinates based on the independent parameters; and
obtaining, based on the complete parameter set, parameters that describe differential characteristics of the geometric structure in the first-level generalized coordinates.

11. The method according to claim 10, further comprising:
constructing second-level generalized coordinates based on the first-level generalized coordinates; and
normalizing the first-level generalized coordinates by using the second-level generalized coordinates.

12. The method according to claim 1, wherein the basic geometric structure of the magnetic shielding apparatus is a geometric structure provided with at least one opening, centers of the basic geometric structures of the N layers of shields do not coincide with each other, and the opening connects the region of interest with outer space of the N layers of shields.

13. The method according to claim 12, wherein the basic geometric structure of the magnetic shielding apparatus is a cylindrical structure with cylindrical symmetry and a single end open, a ring structure extending in a direction from an outer edge of the shield to an axis of symmetry of the cylindrical structure is provided at an opening of at least one layer of shield in the N−1 layers of shields, and the ring structure shields a gap, perpendicular to a direction of the axis of symmetry, between adjacent shields; and
the complete parameter set is used to represent parameters of a symmetrical section of the cylindrical structure.

14. The method according to claim 13, wherein an opening of each of N−1 layers of shields, in the layers of shields, except an innermost layer of shield is provided with the ring structure.

15. The method according to claim 13, wherein the parameters in the complete parameter set comprise a radius Rᵢ of a bottom surface of the cylindrical structure, an axial distance L_{Ai} from the bottom surface of the cylindrical structure to a center of the region of interest, an axial distance L_{Bi} from each layer of shield in the N layers of shields to the center of the region of interest, and a width Cᵢ of the ring structure, wherein i denotes the i^{th} layer of shield, wherein
when each layer of shield in the N layers of shields is provided with the ring structure, L_{Bi} is an axial distance from a geometric center of the ring structure to the center of the region of interest; and
when at least one layer of shield in the N layers of shields is not provided with the ring structure, for a shield not provided with the ring structure, L_{Bi} is an axial distance from an outer edge of the shield not provided with the ring structure to the center of the region of interest; and for the shield, in the N layers of shields, provided with the ring structure, L_{Bi} is an axial distance from a geometric center of the ring structure to the center of the region of interest.

16. The method according to claim 15, wherein range limits are imposed on the parameters in the complete parameter set by constraints, wherein the constraints comprise:
an outer-size constraint, used to define a maximum outer boundary of the magnetic shielding apparatus;
an inner-size constraint, used to define a minimum internal space of the magnetic shielding apparatus;
a spacing constraint, used to define a minimum spacing between adjacent shields;
a minimum-width constraint, used to define a minimum width of the ring structure; and
a region-of-interest constraint, used to define a minimum axial distance from the region of interest to a bottom surface of the innermost layer of shield of the magnetic shielding apparatus.

17. The method according to claim 16, wherein the constraints further comprise an additional constraint, and the additional constraint is used to limit a radius difference of outer layers of adjacent shields to be greater than that of inner layers of the adjacent shields, namely Rᵢ₊₁−Rᵢ>Rᵢ−Rᵢ₋₁.

18. An electronic device, wherein the electronic device comprises:
a processor; and
a memory, configured to store instructions executable by the processor, wherein
the processor is configured to perform the method for designing a magnetic shielding apparatus according to claim 1.

19. A magnetic shielding apparatus, comprising: N layers of shields nested together, wherein N>1, and the magnetic shielding apparatus is designed based on the method for designing a magnetic shielding apparatus according to claim 1.

20. The magnetic shielding apparatus according to claim 19, wherein there is a length difference between adjacent shields of the N layers of shields at at least one of two ends in a working direction of the magnetic shielding apparatus, and/or there is an assembly gap between adjacent shields in the N layers of shields in a direction perpendicular to a working direction of the magnetic shielding apparatus, and the length difference and the assembly gap are designed based on the method for designing a magnetic shielding apparatus; and
at least three layers of shields are provided for the N layers of shields, and at least two assembly gaps between every two adjacent shields are not equal and/or at least two length differences between every two adjacent shields are not equal.
